(19) United States
(12) Patent Application Publication
(10) Pub. No.: US 2022/0294444 A1
(43) Pub. Date: Sep. 15, 2022

(54) LOW LATENCY TACTILE CAPACITIVE KEYBOARDS

(71) Applicant: Intel Corporation, Santa Clara, CA (US)

(72) Inventors: Chun-Ting Liu, Taipei City (TW); Tai Lan Chu, New Taipei City (TW); Arvind S, Bangalore (IN); Gavin Sung, Taipei (TW)

(21) Appl. No.: 17/710,541

(22) Filed: Mar. 31, 2022

(51) Int. Cl. H03K 17/96; G06F 3/02; G06F 3/04883; G06F 3/16

(52) U.S. Cl. CPC H03K 17/9622; G06F 3/021; G06F 3/04883; G06F 3/165

(57) ABSTRACT

Example low latency tactile capacitive keyboards are disclosed. An example compute system includes a keyboard including a housing, a plurality of keys, and a touch sensor positioned between the housing and at least one of the plurality of keys, keyboard circuitry to detect a signal output by the touch sensor, the signal corresponding to a keystroke, and generate a code corresponding to the detected signal and processor circuitry to process the code to effect the keystroke.

### FIELD OF THE DISCLOSURE

This disclosure relates generally to peripheral devices and, more particularly, to low latency tactile capacitive keyboards.

### BACKGROUND

An electronic device generally works by receiving input, processing the input, and providing an output. A human interaction device (HID) is a specific type of peripheral device that enables a user to interact with the electronic device. The electronic device can obtain an input from the user via an input HID such as a touchscreen, a mouse, a keyboard, and/or any other type(s) of input device. When the user types on the keyboard, for example, the keyboard sends a signal to the electronic device that tells the electronic device what keystrokes the user input. The electronic device processes the input and provides an output to the user via an output device, such as a display screen.

### BRIEF DESCRIPTION OF THE DRAWINGS

FIG. 1 is a block diagram of an example system constructed in accordance with the teachings of this disclosure for processing an input received via an example tactile capacitive keyboard.

FIG. 2 is an illustration of an example end-to-end system latency associated with a simulation executing on an electronic device.

FIGS. 3A and 3B are schematic illustrations of an example key of the tactile capacitive keyboard of FIG. 1 in a resting position and in a depressed position, respectively.

FIG. 4 is a block diagram of the example keyboard circuitry of FIG. 1 to detect an input received at the example tactile capacitive keyboard.

FIG. 5 is a block diagram of the example keyboard controller circuitry of FIG. 1 to facilitate processing of the input received at the example tactile capacitive keyboard.

FIG. 6 is a block diagram of an example framework for processing an input received from the tactile capacitive keyboard in accordance with the teachings of this disclosure.

FIG. 7 is a block diagram of an example implementation of the keyboard circuitry of FIG. 4 and the keyboard controller circuitry of FIG. 5 for processing an input received from the tactile capacitive keyboard.

FIG. 8A illustrates an example operational keystroke of a conventional keyboard.

FIG. 8B illustrates an example operational keystroke of the example tactile capacitive keyboard.

FIG. 9A is a partial view of the example tactile capacitive keyboard illustrating a rubber dome enclosure below a keycap.

FIG. 9B is a partial view of the example tactile capacitive keyboard illustrating an example touch sensor below the rubber dome enclosure of FIG. 9A in accordance with the teachings of this disclosure.

FIG. 10A is a graph illustrating a capacitive reading of a finger hovering above a key of the tactile capacitive keyboard at a first distance.

FIG. 10B is a graph illustrating a capacitive reading of a finger hovering above a key of the tactile capacitive keyboard at a second distance.

FIG. 10C is a graph illustrating a capacitive reading of a multi-finger touch at the tactile capacitive keyboard.

FIG. 11 illustrates example gesture controls that can be implemented by the example tactile capacitive keyboard.

FIG. 12 illustrates other example gestures controls that can be implemented by the example tactile capacitive keyboard.

FIG. 13 illustrates an example implementation of the example tactile capacitive keyboard in accordance with the teachings of this disclosure, wherein a plurality of keys less than all the keys of the keyboard are adjusted to have increased sensitivity.

FIG. 14 is a graph illustrating a shorted operational keyboard of the tactile capacitive keyboard as compared to a conventional mechanical keyboard.

FIG. 15 is a graph comparing a latency associated with the example tactile capacitive keyboard as compared to an example optical keyboard.

FIG. 16 is a flowchart representative of example machine readable instructions and/or example operations that may be executed by example processor circuitry to implement the keyboard circuitry of FIGS. 1, 4, 6, and/or 7.

FIG. 17 is a flowchart representative of example machine readable instructions and/or example operations that may be executed by example processor circuitry to implement the keyboard controller circuitry of FIGS. 1, 5, 6, and/or 7.

FIG. 18 is a block diagram of an example processing platform including processor circuitry structured to execute the example machine readable instructions and/or the example operations of FIG. 16 to implement the keyboard circuitry of FIGS. 1, 4, 6, and/or 7 and/or FIG. 17 to implement the keyboard controller circuitry of FIGS. FIGS. 1, 5, 6, and/or 7.

FIG. 19 is a block diagram of an example implementation of the processor circuitry of FIG. 18.

FIG. 20 is a block diagram of another example implementation of the processor circuitry of FIG. 19.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” refer to dimensions that may not be exact due to manufacturing tolerances and/or other real world imperfections. As used herein “substantially real time” refers to occurrence in a near instantaneous manner recognizing there may be real world delays for computing time, transmission, etc. Thus, unless otherwise specified, “substantially real time” refers to real time +/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmed with instructions to perform specific operations and including one or more semiconductor-based logic devices (e.g., electrical hardware implemented by one or more transistors). Examples of processor circuitry include programmed microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of the processing circuitry is/are best suited to execute the computing task(s).

### DETAILED DESCRIPTION

A keyboard is a type of human interaction device (HID) that enables a user to provide input to an electronic device by pressing down a key corresponding to an alpha-numeric character, function, and/or command. A time delay between the user pressing down the key and an effect at the electronic device is referred to as a latency. In reality, the user experiences a variety of latencies between inputting the command and seeing the effect, a combination of which is sometimes referred to as end-to-end latency. Experiencing such latency (e.g., between inputting a command and seeing the effect) can be frustrating for any user. However, the latency can ruin a user experience during a simulation usage of the electronic device such as, for example, while playing a video game.

Latency is a persistent concern in the video game industry. End-to-end system latency as disclosed herein is a flight time starting from a user entering an input into a keyboard and viewing a pixel response at a display screen. End-to-end system latency includes peripheral latency, electronic device latency, and display latency. For example, the end-to-end system latency corresponding to the keyboard includes the keyboard detecting an input by the user and transmitting the input event to the electronic device (e.g., peripheral latency), the electronic device receiving and processing the input event (e.g., electronic device latency), and the effect of the input being displayed on the display screen (e.g., display latency).

Gaming enthusiasts are constantly looking for latency reduction solutions to increase the gaming user experience. For example, a first-person shooter type simulation needs nearly instantaneous feedback from a HID for accurate and effective gameplay. Reducing latencies in the end-to-end system latency of the first-person shooter simulation or other gaming environment could considerably increase satisfaction, enjoyment, and competitive edge of the user's experience. In some situations, latency reduction is critical for a user to win a game. For example, latency experienced by the user during gameplay can be the difference between the user winning or losing the game. Consequently, electronic sports (e.g., esports) competitors are avidly searching for ways to take advantage of a shorter latency. Esports is a form of competition in which participants compete by playing a video game. The results of an esport competition between two similarly capable (e.g., skillful) players can by determined by one player achieving a reduced latency as compared to their adversary. Accordingly, a keyboard that reduces the end-to-end latency could have a substantial impact on a gaming user experience and/or a user experience of other electronic device users.

A conventional mechanical keyboard typically includes a plurality of keys positioned above a corresponding plurality of switches. A switch is an electronic component that can connect and/or disconnect an electrical circuit. The plurality of switches are positioned above a key matrix, which is an interconnected grid of circuits. Each of the circuits is broken at a point below a respective key and switch. An electric current is provided to the key matrix and remains flowing through the key matrix while the keyboard is powered on. To generate an input, the user (e.g., operator, etc.) presses down a key far enough such that a respective switch closes (e.g., completes, etc.) a respective circuit of the key matrix. The action of the user pressing down the key far enough to cause the switch to complete the circuit (e.g., enabling electric current to flow through the circuit) is often referred to as a keystroke. As disclosed herein, a keystroke refers to an effect of a key press that moves a key far enough to be registered (e.g., perceived, sensed, etc.) by processing circuitry of the keyboard. As disclosed herein, an operational keystroke refers to a distance the key travels to achieve the keystroke. For example, the operational keystroke for the conventional mechanical keyboard is a travel distance of a key between the key in a resting position and the key in a position that closes a respective circuit.

In some examples, a processor within the keyboard is structured, configured, or programmed to periodically scan the key matrix to identify a current state of the key matrix to detect a closed circuit. A rate at which the processor scans the key matrix is referred to as a scan rate. Upon detection of the closed circuit, the processor can interpret the closed circuit as an intended keystroke for the key associated with and/or at the location of the closed circuit. In some examples, the processor converts the keystroke into a code (e.g., key code, scan code, etc.) that the electronic device can understand. Converting the keystroke to the scan code enables the electronic device to process the keystroke and respond accordingly. For example, each key of the keyboard can be assigned two or more unique codes (e.g., identifiers) such as a number(s), letter(s), and/or combination thereof. For example, a first code corresponding to the key can represent a press of the key and a second code corresponding to the key can represent a release of the key. In some examples, the scan code corresponds to a binary code, such as an American Standard Code for Information Interchange (ASCII) code. The processor can store the scan code in a memory buffer until the scan code is transmitted to the electronic device.

An optical keyboard is a type of keyboard that utilizes optical switches below the plurality of keys (e.g., as opposed to the electrical switches of the mechanical keyboard). Whereas some mechanical keyboards rely on electric current flowing through the key matrix to identify keystrokes, optical switches use a process called light induction to identify a keystroke. In some examples, the optical keyboard includes a key(s), below which rests an infrared (IR) light emitting diode (LED), a first lens positioned above the IR LED, an IR sensor positioned adjacent the IR LED, and a second lens positioned above the IR sensor. In operation, light can be emitted upward from the IR LED and impinge the first lens, which can propagate the light at a first angle (e.g., a 90 degree angle) such that the light propagates over the IR sensor. In some examples, the second lens is attached to a key. When a user presses down the key far enough to achieve a keystroke, the light hits the second lens, which propagates the light at a second angle towards the IR sensor. The IR sensor can detect the light and signal to the electronic device that the key has been pressed.

Some optical keyboards can achieve a reduced latency as compared to the conventional mechanical keyboard. However, optical keyboards still operate with peripheral latency. Further, optical keyboards have numerous disadvantages. For one, the use of optical switches results in a thick keyboard stacking. As disclosed herein, the stacking refers to a distance from a bottom of a keyboard assembly (e.g., bottom of the key matrix, bottom of an IR LED, etc.) to a top of a key cap. In other words, the stacking is a height of the keyboard assembly in a resting position. In some examples, an optical keyboard stacking is greater than 4.75 millimeters (mm), which is relatively thick compared to other types of keyboards. Further, optical gaming keyboards are typically expensive as compared to the conventional mechanical keyboard and/or other keyboards on the market. A reason for such higher costs is the complex the design required for the optical keyboard. For example, the optical keyboard requires multiple optical devices (e.g., the IR LED, the lenses, the IR sensor, etc.) underneath each keycap of the keyboard. Based on the foregoing, a new keyboard that operates with limited end-to-end latency at an affordable cost is needed.

Keyboards can operate in different manners depending on a type of keyboard and how the keyboard communicates (e.g., interfaces) with the electronic device. A keyboard of a laptop typically operates different than a keyboard that is separate from, but communicatively coupled to, the electronic device (e.g., via a universal serial bus (USB) interface connection, a Bluetooth connection, a PS/2 port, etc.). For example, the laptop keyboard can include dedicated circuitry within the electronic device that scans the key matrix and generates the scan code (e.g., instead of a processor within the keyboard). In some examples, the separate keyboard relies at least partially on established protocols to receive and process input received at the keyboard. Examples disclosed below are discussed in terms of the separate keyboard that is communicatively coupled to the electronic device and uses USB-type protocols to interface with the electronic device. However, it is understood that examples disclosed herein can be applied to other types of keyboards additionally or alternatively, such as the laptop keyboard, a detachable keyboard, etc. Further, it is understood that examples disclosed herein can be applied to keyboards that have other types of interfaces, such as a dedicated interface, PS/2 port connection, Bluetooth connection, etc.

Methods, systems, apparatus, and articles of manufacture disclosed herein provide for reduced end-to-end system latency associated with a keyboard input. As noted above, end-to-end system latency associated with the keyboard input includes the peripheral latency, the electronic device latency, and the display latency. Examples disclosed herein aim to improve the peripheral latency by employing an example tactile capacitive keyboard constructed in accordance with the teachings of this disclosure. In some examples, the end-to-end latency associated with the example tactile capacitive keyboard is less than 20 milliseconds (ms). For example, an end-to-end gaming latency associated with input received at the example tactile capacitive keyboard can be as little as 10 ms, which shows very positive trend to outperform other existing gaming keyboards.

Example tactile capacitive keyboards disclosed herein are constructed to limit and/or otherwise eliminate the peripheral latency. In some examples, the tactile capacitive keyboard can reduce the peripheral latency by shortening an operational keystroke. For example, shortening the operational keystroke can enable the keyboard to register and process the input sooner. Example tactile capacitive keyboards disclosed herein reduce the operational keystroke by including a plurality of keys and at least one touch sensor positioned beneath at least one key of the plurality of keys. The touch sensor is a device that detects physical touch and/or proximate touch caused by a user. For example, the touch sensor can detect physical touch and/or proximate touch by detecting a change in capacitance at the touch sensor caused by the user's finger. The example tactile capacitive keyboard can detect the touch and/or proximate touch and interpret the touch as an intended keystroke for a location of the touch.

By registering an input event upon detection of the touch and/or proximate touch, example tactile input keyboards disclosed herein can reduce the operational keystroke. For example, the operational keystroke of the conventional mechanical keyboard requires the user to press the key down far enough to close a respective circuit. The keystroke of the example tactile capacitive keyboard is detected when the user effects a change in capacitance of the touch sensor. Capacitance of a touch sensor is changed with a smaller operational keystroke than that associated with the mechanical pressing of the key to close a circuit. Reducing the operational keystroke to register an input enables the example tactile capacitive keyboard to detect and process an input faster.

In some examples, the operational keystroke of the tactile capacitive keyboard is determined by (e.g., proportional to) a sensitivity of the touch sensor. Certain examples disclosed herein enable a user to program (e.g., set, select, etc.) an operational keystroke. Thus, examples disclosed herein allow the sensitivity of the touch sensor to be adjusted (e.g., increased, decreased, etc.) to shorten (e.g., and/or lengthen) the operational keystroke. Thus, in some examples, the operational keystroke of the example tactile capacitive keyboard is a distance a key travels to allow the touch sensor to sense a change in capacitance. In other examples, the operational keystroke of the example tactile capacitive keyboard is a distance the user's finger and/or other suitable component (e.g., a stylus) is from the touch sensor to enable the keyboard to detect the change in capacitance. In some examples, the keys are not depressed but, rather, the keyboard detects a change in capacitance when a user's finger(s), stylus, and/or other object is above, but not depressing, a key. Thus, in some examples, a keystroke does not include a user's finger and/or other suitable component coming into physical contact with a key.

Examples disclosed herein utilize a capacitive touch sensor below the keys of the example tactile capacitive keyboard. However, other types of touch sensors may be used additionally or alternatively, such as a resistive touch sensor, surface acoustic wave (SAW) touch sensor, and/or infrared (IR) touch sensor, etc. In some examples, the touch sensor implements a key matrix of the example tactile capacitive keyboard.

In some examples, the example tactile capacitive keyboard can include a surface capacitive touch sensor. In some such examples, the surface capacitive touch sensor includes at least four electrodes (e.g., one in each corner of the keyboard), which apply a substantially uniform flow of electric current throughout the touch sensor. The user can generate an input by applying a touch (e.g., via a finger, which is an electrical conductor, and/or a stylus holding an electric charge) to a key positioned above the touch sensor. The user's touch acts as a capacitor and changes an amount of electric current flowing through the touch sensor at that location. For example, when the user's finger touches the key, the touch sensor can react to the static electrical capacity of the finger and at least some electrical charge can transfer from the electrodes to the user's finger. In other words, the user's finger can pull a small charge from the electrodes upon the touch. The location (e.g., coordinates) of the touch can be determined by identifying a point within the touch sensor where the change in capacitance occurred and calculating the location based on distances of the point relative to the at least four electrodes of the touch sensor.

In examples disclosed herein, the example tactile capacitive keyboard includes a projective capacitive touch sensor. In some examples, the projective capacitive touch sensor includes a matrix of conductive elements made from electrically conductive materials such as indium tin oxide (ITO), silver, copper, carbon, etc. The conductive elements can be arranged in layers, such an X layer and a Y layer with an insulation layer positioned therebetween. For example, the X layer can include rows of conductive elements (e.g., electrodes) and the Y layer can include columns of electrodes. In operation, an electric current can be applied to the conductive matrix. To provide an input, the user can approach a key using a finger and/or stylus. Once the user is close enough to the key, a change in the capacitive field of the conductive matrix is generated. A location of the touch and/or proximate touch can be determined by identifying a region of the conductive matrix that experienced the greatest change in capacitance and determining the regions position within the X and Y layers.

In some examples, the example tactile capacitive input is hovering-enabled. For example, the touch sensor sensitivity can be adjusted such that the touch sensor can register a touch that is proximate the key. Thus, some example tactile capacitive keyboards disclosed herein do not require physical contact with the key to register a keystroke as an input.

Certain example tactile capacitive keyboards disclosed herein further reduce the peripheral latency by reducing a time spent debouncing an input. When the user presses down a key for a single keystroke, a vibration can occur that causes the single keystroke to actuate (e.g., move up and down) numerous times. For example, the vibration in a conventional mechanical keyboard can cause a switch to open and/or close a circuit multiple times. To prevent the vibration of the single keystroke from registering as more than one keystroke, processing circuitry can perform a debouncing function to remove noise caused by the bouncing. Thus, debouncing is a process in which processing circuitry filters out the vibrations. In some examples, debouncing includes detecting the bounce and aggregating the corresponding fluctuations into one keystroke. By integrating the touch sensor below the plurality of keys, keystrokes for example tactile capacitive keyboards disclosed herein can include little to no bouncing noise. Because the touch sensor produces little to no bouncing noise, example tactile capacitive keyboards disclosed herein spend little to no time performing the debouncing function. Consequently, the keystroke can be reported to the electronic device sooner to further reduce the peripheral latency.

Certain example tactile capacitive keyboards disclosed herein reduce the peripheral latency by increasing (e.g., improving) a response time to an input event (e.g., a touch and/or proximate touch). In some examples, the tactile capacitive keyboard can respond to an input faster by increasing a scan rate of the keyboard. The scan rate indicates a frequency of which the keyboard's processing circuitry scans the key matrix (e.g., the touch sensor) to identify a chance in capacitance (e.g., a touch). For example, the scan rate can be identified by a number of scans (e.g., cycles) per second. By increasing the scan rate, the tactile capacitive keyboard can detect the input touch sooner, enabling the tactile capacitive keyboard to report the input touch sooner. In some examples, the processing circuitry scans the key matrix at a scan rate of approximately 250 Hertz (Hz). In other examples, other scan rates may be used.

In some examples, the tactile capacitive keyboard provides for reduced peripheral latency in a cost-effective manner (e.g., as compared to an optical keyboard and/or other gaming keyboards). Example tactile capacitive keyboards disclosed herein include relatively thin stacking (e.g., as compared to an optical keyboard). In some examples, the stacking is approximately 3.25 mm.

Certain examples disclosed herein improve an electronic device latency associated with the tactile capacitive keyboard. In some examples disclosed herein, the electronic device latency is reduced by increasing a polling rate of the example tactile capacitive keyboard. For example, a keyboard controller of the electronic device can be structured to poll the tactile capacitive keyboard at a higher frequency to detect the input received at the tactile capacitive keyboard sooner. Similar to the scan rate of the keyboard, the polling rate is the frequency at which the electronic device (e.g., via a keyboard controller) polls (e.g., surveys) the keyboard. For example, the keyboard controller can poll the keyboard by requesting that the keyboard send any data (e.g., scan codes) it has stored in a buffer. Increasing the polling rate enables faster reporting of the input by the keyboard to the keyboard controller. Faster reporting of the input event to the keyboard controller allows the keyboard controller to report the input even to a process sooner, enabling the processor to process the scan code sooner. In some examples disclosed herein, the polling rate is at least 1,000 Hz. In other examples, other polling rates may be used.

Certain examples disclosed herein include a dedicated serial peripheral interface (SPI) between the example tactile capacitive keyboard and the keyboard controller. Some electronic devices include a chipset that controls (e.g., manages) communication between a processor and components of the electronic device such as the keyboard. For example, the chipset can be an input/output (I/O) controller hub on a motherboard of the electronic device. The chipset can manage various peripherals devices that rely on the processor to process data. Typically, data from the keyboard is transported to the keyboard controller and to the processor via the chipset, which includes numerous controllers and drivers. The dedicated SPI can enable the tactile capacitive keyboard can report the input event directly to the keyboard controller rather than via a chipset. Thus, integrating the dedicated SPI can enable faster reporting of an input event to the electronic device to reduce the electronic device latency associated with the keyboard.

Certain examples disclosed herein reduce the electronic latency by including an example hardware accelerator that is structured to process an input received at the tactile capacitive keyboard. Hardware acceleration refers to an electronic device processing task that is offloaded to another piece of hardware that is not a main processor, such as a CPU, which typically handles a majority of the electronic device's processing. Absent the hardware accelerator, the scan code corresponding to the input event at the keyboard may have to wait to be processed until the CPU is ready. However, a hardware accelerator can be programmed to process the input event received at the keyboard to further reduce the electronic device latency. For example, the hardware accelerator may be able to process the input event sooner than the CPU. In some examples, the keyboard controller can report the input event directly to the hardware accelerator rather than generating an interrupt at the CPU. In some examples, the hardware accelerator can have a considerable impact on the processing speed of keystrokes.

Example tactile capacitive keyboards disclosed herein can be implemented in a variety of manners. The example tactile capacitive keyboard can be equipped with light emitting diodes (LEDs) and/or other appearance features desirable to a user. In some examples, the example tactile capacitive keyboard includes a tactile feel that is similar to a conventional mechanical keyboard. In some examples, the example tactile capacitive keyboard can be programmed to include gesture controls. For example, a key(s) on the tactile capacitive keyboard can be configured to scroll up and/or down, zoom in and/or out, rotate, etc. on an application window via gestures of the user's finger. Examples disclosed below refer to a touch as received by a user's finger(s). However, it is understood that the touch can be implemented by anything capable of carrying an electric charge, such as a stylus, a finger with a glove, another body part, etc.

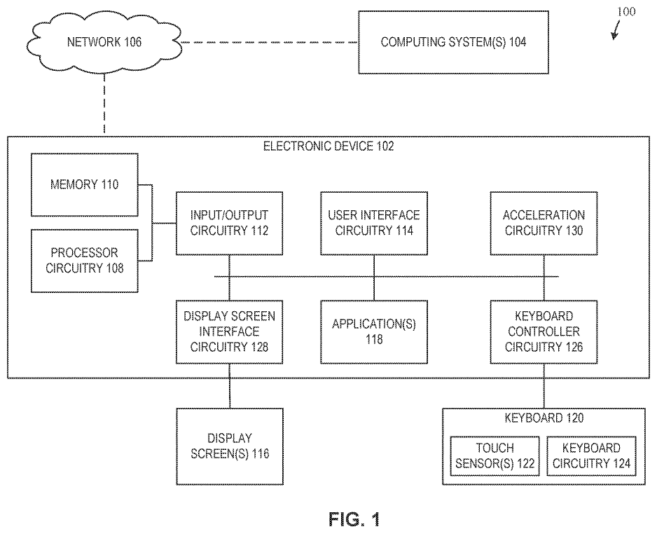

FIG. 1 is a block diagram of an example system 100 constructed in accordance with the teachings of this disclosure for processing user input received via a keyboard. The system 100 includes an example electronic device 102, which can implement any suitable electronic device, such as a personal computer (PC) device (e.g., desktop, laptop, an electronic tablet, etc.), a gaming system, a smartphone, etc. In some examples, the electronic device 102 is in communication with another computer system(s) 104 via an example network 106. For example, the electronic device 102 may be in communication with the other computer system 104 while playing a video game, such as an online multi-player video game. In some examples, the electronic device 102 is in communication with the other computer system 104 during an esports competition. The other computer system(s) 104 can be any suitable computer system(s), such as a personal computer, a gaming system, a laptop, etc.

The example network 106 may be implemented using any network over which data can be transferred, such as the Internet. The example network 106 may be implemented using any suitable wired and/or wireless network(s) including, for example, one or more data buses, one or more Local Area Networks (LANs), one or more wireless LANs, one or more cellular networks, one or more private networks, one or more public networks, among others. In additional or alternative examples, the network 106 is an enterprise network (e.g., within businesses, corporations, etc.), a home network, among others.

The example electronic device 102 includes example processor circuitry 108, example memory 110, and example input/output circuitry 112. The processor circuitry 108 is structured to execute machine readable instructions (e.g., software) including, for example, user applications, an operating system, etc. The example processor circuitry 108 is a semiconductor-based hardware logic device. The processor circuitry 108 may implement a central processing unit (CPU) of the electronic device 102, may include any number of cores, and may be implemented, for example, by commercially available processing circuitry. In some examples, the processor circuitry 108 is communicatively coupled to additional processing circuitry.

The example memory 110 is structured to store data, such as programs, peripheral component data, an operating system, etc. For example, the memory 110 can store data packets received by an application, a HID in communication with the electronic device 102, etc. In some examples, the memory 110 can store various data to be used by the processor circuitry 108 to perform functions, such as those disclosed herein. In some examples, the memory 110 can be one or more memory systems that include various types of computer memory. In some examples, the memory 110 may be implemented by a volatile memory (e.g., a Synchronous Dynamic Random Access Memory (SDRAM), a Dynamic Random Access Memory (DRAM), a RAMBUS Dynamic Random Access Memory (RDRAM), a double data rate (DDR) memory, such as DDR, DDR2, DDR3, DDR4, mobile DDR (mDDR), etc.)) and/or a non-volatile memory (e.g., flash memory, a hard disk drive (HDD), etc.).

The example input/output circuitry 112 is constructed to interface between the processor circuitry 108 and/or the memory 110, and other components of the electronic device 102. In some examples, the input/output circuitry 112 implements a Basic Input Output Subsystem (BIOS). In some examples, the input/output circuitry 112 implements an input/output subsystem. In some examples, the input/output circuitry 112 implements a chipset, such as a controller hub.

The example electronic device 102 of FIG. 1 includes example user interface circuitry 114, which is structured to enable a user to interact with the electronic device 102. For example, the user interface circuitry 114 includes a graphical user interface (GUI), an application display, etc., presented to a user on an example display screen 116 in circuit with and/or otherwise in communication with the electronic device 102. In some examples, the user controls the electronic device 102, configures one(s) of the hardware, firmware, and/or software resources of the electronic device 102, etc., by the user interface circuitry 114. In some examples, the user interface circuitry 114 enables the electronic device 102 to obtain information from the user via an input device and provide information to the user via an output device.

The electronic device 102 of FIG. 1 includes example application(s) 118, which may correspond to any application that can be implemented by the electronic device 102. In some examples, the application 118 is a simulation-type application, such as a video game. In some examples, the user interacts with the electronic device 102 by accessing one or more applications 118 (e.g., a web browser, a video player, a music streaming platform, a word processing application, etc.) executed by the processor circuitry 108 of the electronic device 102. The user can view digital content associated with the one or more applications 118 (e.g., digital images, webpages, videos, electronic documents, etc.) via the display screen 116.

The electronic device 102 of FIG. 1 is communicatively coupled to the example display screen(s) 116 (e.g., via a wired and/or wireless connection). The display screen 116 may be any suitable display device, such as a touchscreen display, a liquid crystal display (LCD), a projector, etc. In some examples, the display screen 116 is physically attached to the electronic device 102, such as when the electronic device 102 is a laptop. In some examples, the display screen 116 is communicatively coupled to the electronic device 102, such as when the electronic device 102 is a personal computing device that is coupled to a monitor. In some examples, the electronic device 102 is communicatively coupled to more than one display screen 116. In some examples, the display screen 116 includes a high refresh rate to reduce a display latency. For example, the refresh rate of the display screen 116 is approximately 240 Hz in some examples.

The electronic device 102 is communicatively coupled to an example tactile capacitive keyboard (e.g., keyboard) 120. In some examples, the keyboard 120 is a component of the electronic device 102. For example, the keyboard 120 may be a keyboard of a laptop. In some examples, the keyboard 120 may be detachable from the electronic device 102, such as with a convertible laptop. In some examples, the keyboard 120 is a separate component that is communicatively coupled to the electronic device 102 via a wireless and/or wired connection.

In some examples, the user interacts with the electronic device 102 using the tactile capacitive keyboard 120 and/or the display screen 116. In some examples, the user interacts with the electronic device 102 using the keyboard 120 and the display screen 116 via the user interface circuitry 114, which implements an interface between the user and the electronic device 102. For example, the user can utilize the user interface circuitry 114 to provide an input to the electronic device 102 via the keyboard 120 and view a corresponding output at the display screen 116.

In the illustrated example of FIG. 1, the example tactile capacitive keyboard 120 is a separate component from the electronic device 102 that is communicatively coupled to the electronic device 102. The tactile capacitive keyboard 120 includes a plurality of keys and a housing that carries components of the keyboard 120. Each key of the example keyboard 120 includes a keycap having text that indicates the key's utility (e.g., letter, number, command, function, etc.) and a movement mechanism coupled to the keycap and to a base plate coupled to the housing. The movement mechanism enables a user to press down the keycap to generate an input and returns the keycap to a resting (e.g., idle) position when the user releases the keycap. For example, the movement mechanism can be a lever, a butterfly assembly, a scissor mechanism, etc.

The tactile capacitive keyboard 120 includes an example touch sensor 122 positioned between the keyboard housing and at least one key of the plurality of keys (e.g., below the base plate). In some examples, the touch sensor 122 implements a key matrix of the keyboard 120. In the illustrated example of FIG. 1, the touch sensor 122 is a projective capacitive touch sensor. In some examples, the touch sensor 122 can recognize between 10 and 80 discrete touch points. In some examples, the touch sensor 122 can detect approximately 16 points. The touch sensor 122 of FIG. 1 is mutual capacitive. However, the touch sensor 122 can be self-capacitive in additional or alternative examples. In some examples, there are more than one touch sensors 122.

To perform a keystroke, the user can touch a key corresponding to the desired keystroke using a finger and/or other electric charge carrying component, such as a stylus. In some examples, the user can achieve an operational keystroke by depressing the key at least a distance that satisfies a threshold distance. In some examples, the user can adjust a sensitivity of the touch sensor 122. In some examples, the sensitivity of the touch sensor 122 corresponds to the threshold distance. For example, the sensitivity of the touch sensor 122 can be increased to reduce the threshold distance. In some examples, the keystroke is achieved by placing the finger and/or stylus proximate the key, depending on a sensitivity of the touch sensor 122. Accordingly, an operational keystroke of the tactile capacitive keyboard 120 can be dependent on a current sensitivity of the touch sensor 122. In some examples, the sensitivity of the touch sensor 122 can be increased such that the user can hover above a key to achieve a keystroke for that key. In some such examples, the keystroke includes the touch sensor 122 sensing a presence of a finger or object within a threshold distance above at least one key.

In some examples, the user can program an application specific sensitivity of the touch sensor 122 of the tactile capacitive keyboard 120. For example, the user can adjust the sensitivity of the touch sensor 122 via a specific application 118. That is, in some examples, the sensitivity of the touch sensor 122 can be set (e.g., automatically) based on an application 118 that is running. In some examples, the user can program a default sensitivity that is applied to the touch sensor 122 by the keyboard circuitry 124, unless a running application applies a different sensitivity of the touch sensor 122. For example, a word processing application could be programmed to be associated with a first sensitivity and a video game application could be programmed to be associated with a second sensitivity. If the word processing application is running, the first sensitivity can be applied to the touch sensor 120. If the video game application is running, the second sensitivity can be applied to the touch sensor 120. In some examples, if both applications are running, the sensitivity of the touch sensor 120 can be determined by which application the user is interacting with (e.g., which application is active). If both applications are running, but neither application is active, the default sensitivity can be applied to the touch sensor 120. In some examples, the default sensitivity, the first sensitivity, and/or the second sensitivity are different. In some examples, one or more of the default sensitivity, the first sensitivity, and/or the second sensitivity can be the same.

In some examples, the user can program gestures into the example tactile capacitive keyboard 120 as gesture controls (e.g., commands, functions, etc.). In some examples, the user can execute a keystroke that includes a gesture corresponding to a command. In some examples, the gesture is within a threshold distance above at least one of the plurality of keys. In some examples, the gesture can be executed by depressing a key at least a threshold distance. In some examples, the gesture is a sliding gesture across at least one of the plurality of keys. In some such examples, the gesture corresponds to an adjustment command, such as brightness adjustment (e.g., of the display screen 116), a volume adjustment (e.g., corresponding to a speaker that is communicatively coupled to the electronic device 102), a touch sensor 122 sensitivity adjustment, etc. In some examples, additional or alternative gestures can be executed that correspond to additional or alternative commands.

The tactile capacitive keyboard 120 includes example keyboard circuitry 124, which is structured to process an input (e.g., a touch) received at the touch sensor 122. The keyboard circuitry 124 detects the input received by the touch sensor 122 by periodically (e.g., and/or aperiodically) scanning the touch sensor 122 to detect a signal(s) output by the touch sensor 122. For example, the signal output by the touch sensor 122 may be a change in capacitive in response to the user pressing down a keycap. In some examples, the keyboard circuitry 124 scans the touch sensor 122 at a scan rate of approximately 250 Hz. In some examples, other scan rates are used.

Upon detection of the keystroke, the keyboard circuitry 124 is structured to identify the keystroke by determining a key(s) corresponding to the touch input. For example, the keyboard circuitry 124 can determine a location of touch and determine a key corresponding to the location. The keyboard circuitry 124 can determine the key by searching the location against a character map to identify what the keystroke(s) represents (e.g., which physical key(s) was pressed and/or released). As disclosed herein, a character map is an organized structure such as a lookup table or comparison chart that allows the processing circuitry to identify a location of each key in the key matrix and what each keystroke (or combination of keystrokes) represents.

In some examples, the keyboard circuitry 124 is structured to generate a scan code corresponding to the identified keystroke. For example, the keyboard circuitry 124 can generate the scan code by converting the identified keystroke into a binary code that the electronic device 102 can understand and recognize as the respective keystroke. The scan code can be an ASCII code, a Unicode, etc. The keyboard circuitry 124 maintains the scan code in a memory buffer. In some examples, the keyboard circuitry 124 transmits the scan code to the electronic device 102.

In some examples, the keyboard circuitry 124 may be implemented by an integrated circuit (IC). In some examples, the keyboard circuitry 124 is implemented by processing circuitry (e.g., a system on a chip (SOC)). In some examples, the keyboard circuitry 124 is instantiated by processor circuitry such as a central processing unit executing instructions. In some examples, the keyboard circuitry 124 may be instantiated by an application specific integrated circuit (ASIC) or a field programmable gate array (FPGA) structured to perform operations corresponding to the instructions.

The electronic device 102 includes example controllers to interface with respective peripheral devices. In the illustrated example of FIG. 1, the electronic device 102 includes example keyboard controller circuitry 126, which can implement a keyboard controller, and example display screen controller circuitry 128, which can implement a display screen controller. The keyboard controller circuitry 126 is structured to interface with the keyboard 120 (e.g., via the keyboard circuitry 124). The keyboard controller circuitry 126 and/or the display screen controller circuitry 128 can be implemented by the processor circuitry 108 of the electronic device 102, or by a different processor or processors.

The keyboard controller circuitry 126 is structured to interface with the tactile capacitive keyboard 120. In some examples, the keyboard controller circuitry 126 can control operating characteristics of the tactile capacitive keyboard 120. In some examples, the keyboard controller circuitry 126 is structured to periodically and/or aperiodically poll the keyboard circuitry 124 to detect a scan code corresponding to an input. In some examples, the keyboard controller circuitry 126 polls the keyboard circuitry 124 at a poll rate of approximately 1,000 Hz. In some examples, other poll rates are used. When the keyboard circuitry 124 indicates to the keyboard controller circuitry 126 that a scan code is available, the keyboard controller circuitry 126 receives and/or retrieves the scan code from the keyboard circuitry 124.

In some examples, the keyboard controller circuitry 126 is structured to generate an interrupt request. For example, the interrupt request can take the form of a signal sent to the input/output circuitry 112, the processor circuitry 108 and/or other processing circuitry. In some examples, the signal causes the processor circuitry 108 to suspend (e.g., interrupt) a current execution and read the scan code.

The display screen controller circuitry 128 is structured to interface with the display screen 116. In some examples, the display screen controller circuitry 128 can control operating characteristics of the display screen 116, such as a display refresh rate and/or other characteristics. In some examples, the display screen controller circuitry 128 controls a refresh rate of the display screen 116 to increase and/or decrease the refresh rate. In some examples, the display screen controller circuitry 128 causes the display screen refresh at a rate of approximately 240 Hz. In some such examples, the refresh rate of approximately 240 Hz can mitigate end-to-end gaming latency by causing a pixel response associated with an input received at the tactile capacitive keyboard 120 sooner. In some examples, other refresh rates may be used. In some examples, the display screen controller circuitry 128 is structured to dynamically reduce a render requeue to reduce a back pressure of the processor circuitry 108, enabling the processor circuitry 108 to process an input event from the keyboard 120 sooner.

In some examples, the electronic device 102 includes example acceleration circuitry 130. In some examples, the acceleration circuitry 130 implements a hardware accelerator. For example, the acceleration circuitry 130 may be implemented by a hardware accelerator configured to accelerate tactile capacitive keyboard input processing. In some examples, the acceleration circuitry 130 is implemented by logic circuitry to perform certain tasks more quickly and/or efficiently than can be done by a general purpose processor. In some examples, the acceleration circuitry 130 may be on-board the processor circuitry 108, in the same chip package as the processor circuitry 108 and/or in one or more separate packages from the processor circuitry 108.

In some examples, the processor circuitry 108 and/or the acceleration circuitry 130 interprets the keystroke corresponding to the scan code using a separate character map that overrides the one found in the keyboard circuitry 124. For example, the electronic device 102 may include a character map that is adjusted by the user to adapt to the user's preferences. In some examples, the processor circuitry 108 and/or the acceleration circuitry 130 interprets or processes the scan code to effect the keystroke corresponding to the scan code.

In some examples, the electronic device of FIG. 1 is referred to as a compute system. As disclosed herein, the compute system is a collection of hardware and software components that are constructed to receive, process, manage, and/or present information in a meaningful and/or useful format.

While an example manner of implementing the electronic device 102 of FIG. 1 is illustrated in FIG. 1, one or more of the elements, processes, and/or devices illustrated in FIG. 1 may be combined, divided, re-arranged, omitted, eliminated, and/or implemented in any other way. Further, the example processor circuitry 108, example input/output circuitry 112, example user interface circuitry 114, example keyboard controller circuitry 126, example display screen interface circuitry 128, example acceleration circuitry 130, and/or, more generally, the example electronic device 102 of FIG. 1, may be implemented by hardware alone or by hardware in combination with software and/or firmware. Thus, for example, any of the example processor circuitry 108, example input/output circuitry 112, example user interface circuitry 114, example keyboard controller circuitry 126, example display screen interface circuitry 128, example acceleration circuitry 130, and/or, more generally, the example electronic device 102, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example electronic device 102 of FIG. 1 may include one or more elements, processes, and/or devices in addition to, or instead of, those illustrated in FIG. 1, and/or may include more than one of any or all of the illustrated elements, processes and devices.

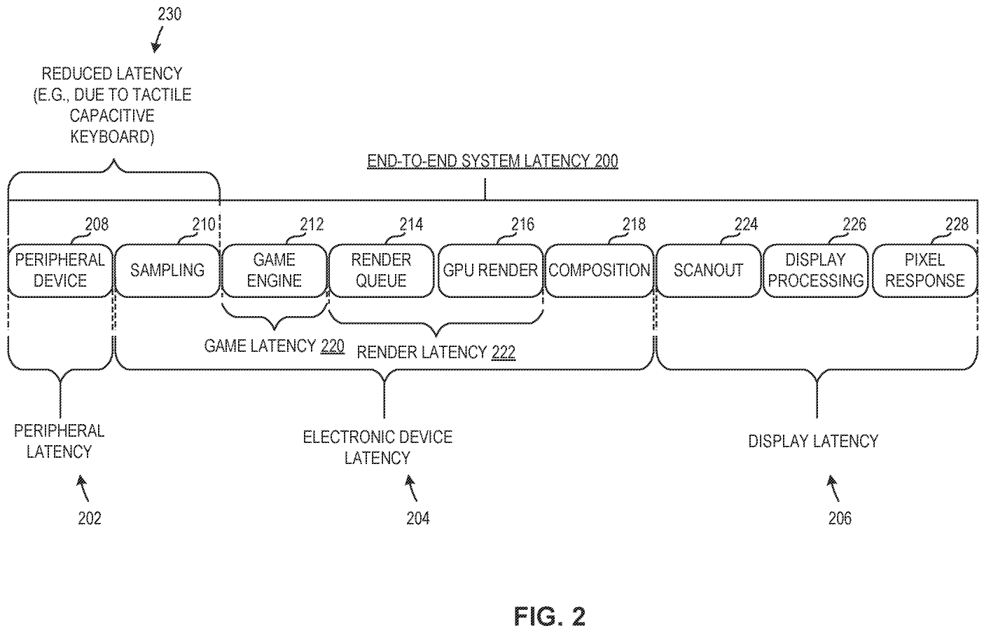

FIG. 2 illustrates an example end-to-end system latency 200 associated with a video game that executes on an electronic device (e.g., electronic device 102 of FIG. 1). The end-to-end system latency 200 includes a peripheral latency 202, an electronic device latency 204, and a display latency 206. A reduction in any constituent latency in the end-to-end latency 200 results in a reduction of the end-to-end latency 200.

The peripheral latency 202 is a latency associated with a peripheral device 208. The peripheral device 208 can be any suitable peripheral device, such as a keyboard (e.g., tactile capacitive keyboard 120 of FIG. 1), a mouse, a gaming controller, a joystick, etc. As discussed above, the peripheral latency 204 can be reduced in a variety of manners depending on the peripheral device 208 and its configuration. The tactile capacitive keyboard 120 of FIG. 1 provides reduced peripheral latency 202 by reducing an operational keystroke (e.g., the travel distance of a key during a key press for the electronic device to detect the keystroke), reducing debouncing operations, and/or increasing a scan rate of a key matrix (e.g., touch sensor 122).

The electronic device latency 204 includes latencies associated with sampling 210, a game engine 212, a render queue 214, a graphics processing unit (GPU) 216, and a composition 218. Sampling 210 refers to a frequency at which a controller or other component of an electronic device samples a status of an external device in communication with the electronic device (e.g., per second). As disclosed herein, the sampling 210 refers to the polling rate, which is the frequency at which a controller (e.g., keyboard controller circuitry 126) polls a respective device (e.g., tactile capacitive keyboard 120). In some examples, if the tactile capacitive keyboard 120 wants to send data (e.g., a scan code) to the controller 126, the tactile capacitive keyboard 120 has to wait until the host 126 asks the tactile capacitive keyboard 120 to do so. A higher polling rate means the tactile capacitive keyboard 120 can deliver data more frequently to the controller 126.

In some examples, the game engine 212 is referred to as a game latency 220. The game engine 212 refers to a simulation, video game and/or application corresponding to a video game. For example, the game engine 212 may be an application (e.g., application 118) that executes on the electronic device 102. In some examples, the game engine 212 is installed on the electronic device 102. In some examples, the game engine 212 may be stored at a cloud (e.g., software as a service (SaaS), gaming as a service (GaaS), etc.) and accessed via a network (e.g., network 106). In other words, the game latency 220 refers to the latency associated with processing an input and/or change to the world and submitting a new frame to the GPU 216 to be rendered. Typically, the video game execution needs to constantly update a state of the world (e.g., the simulation), such as updates to animations, changes to characters in the game due to inputs, etc. The game engine 212 determines where items in the video games need to go in the next frame and send rendering work to a graphics interface (e.g., a graphics driver).

In some examples, the electronic device latency 204 includes the render queue 214. The render queue 214 refers to work (e.g., frames of content) that needs to be processed by the GPU. In some examples, the render queue 214 and the GPU rendering 216 are referred to as a render latency 222. The render latency 222 is a latency associated with causing an image to render on a display screen (e.g., display screen 116). In other words, render latency 222 is a time from the frame being placed in line to be rendered (e.g., the render queue 214) to a time when the GPU completely renders the frame (e.g., GPU rendering 216). In some examples, the GPU rendering 216 refers to a time it takes for the GPU to render all the work associated with a single frame.

In some examples, the electronic device latency 204 includes latency due to composition 218. As disclosed herein, composition 218 refers to a process of putting together different or various elements to generate a display as seen by the user on a display screen (e.g., display screen 116). For example, the electronic device 102 may include additional rendering work to composite for a particular frame, such as scroll bars, borders, menus, icons, etc., which are viewable in addition to the video game rendering. In some examples, the latency due to composition 218 can be reduced by placing the video game in full-screen mode to reduce a time spent on composition 218.

The display latency 206 includes latencies associated with scan out 224, display processing 226, and pixel response 228. Scan out 224 refers to a frame that is ready for display being fed to the display screen 116 and occurs once the composition 218 of a frame is complete. For example, once the final frame buffer is complete and ready to be displayed, the GPU signals to the display screen 116 that the frame buffer is ready for display. In some examples, the scan out 224 is based on the refresh rate (Hz) of the display screen 116. Display processing 226 refers to a time the display screen 116 takes to process the incoming frame and initiate the pixel response 228. Pixel response 228 refers to the time it takes a pixel to change from one color to the next.

Examples disclosed herein provide reduced latency 230 by integrating the example tactile capacitive keyboard 120 of FIG. 1. Examples disclosed herein remove latency from the peripheral latency 202 and the electronic device latency 204. Accordingly, other functions in the end-to-end system latency 200, such as render queue 214, GPU render 216, pixel response 228, etc. can occur sooner, thereby reducing a time between the user inputting a command and viewing the pixel response at the display screen 116.

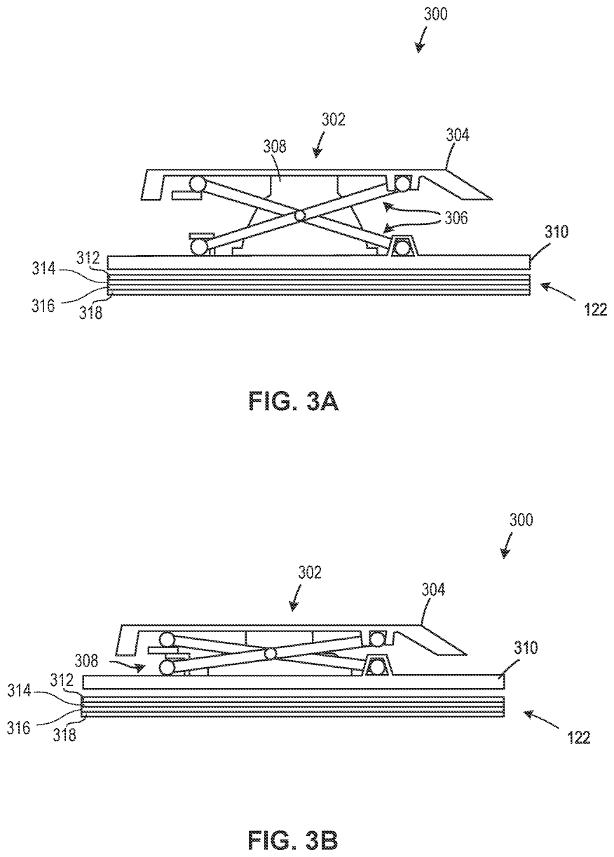

FIGS. 3A and 3B are schematic illustrations of an example key 300 of a tactile capacitive keyboard (e.g., keyboard 120) constructed in accordance with the teachings of this disclosure. The key 300 can correspond to any key on the keyboard 120, such as a letter key, number key, command key, function key, etc. FIG. 3A illustrates the key 300 in a resting position while FIG. 3B illustrates the example key 300 in depressed position (e.g., pressed down, lowered, pushed, compressed, etc.).

The key 300 includes an example identifier (ID) layer 302, example keycap 304, and an example movement mechanism 306. The ID layer 302 is positioned on the example keycap 304. The ID layer 302 indicates a utility associated with the key 300, such as a number, letter, command, etc. The ID layer 302 may be applied to the keycap 304 in any suitable manner, such as printed onto the keycap 304, engraved into the keycap 304, illuminated from beneath the keycap 304, etc. The keycap 304 is a portion of the keyboard 120 that the user interacts with (e.g., contacts) to provide an input. The keycap 304 can be made of any suitable material such as, for example, a plastic. The keycap 304 is coupled to the keyboard 120 via the movement mechanism 306. In the illustrated example of FIG. 3A, the movement mechanism 306 is a scissor mechanism that includes two pieces of plastic that interlock in a scissor-like fashion. The movement mechanism 306 may be a different type of mechanism in additional or alternative examples, such as a butterfly mechanism.

In the illustrated example of FIG. 3A, the key 300 includes an example rubber dome 308. The rubber dome 308 may be manufactured using a flexible material, such as rubber or silicone. The movement mechanism 306 and the rubber dome 308 return the key 300 to the resting position after the key 300 is depressed by the user. The key 300 also includes a back cover 310. The back cover 310 is structured to act a back-stop for the key 300. Further, the back cover 310 is an anchor that remains stationary while the rest of the key 300 is able to move.

The tactile capacity keyboard 120 includes an example touch sensor 122 positioned below the back cover 310. In some examples, the touch sensor 122 is a first touch sensor that corresponds to the key 300. In some such examples, the keyboard 120 can include multiple touch sensors 122, each of which correspond to one or more other keys. In some examples, the touch sensor 122 is a component that is associated with, but separate from, the key 300. In some such examples, the touch sensor 122 may rest below a plurality of keys 300 of the keyboard 120.

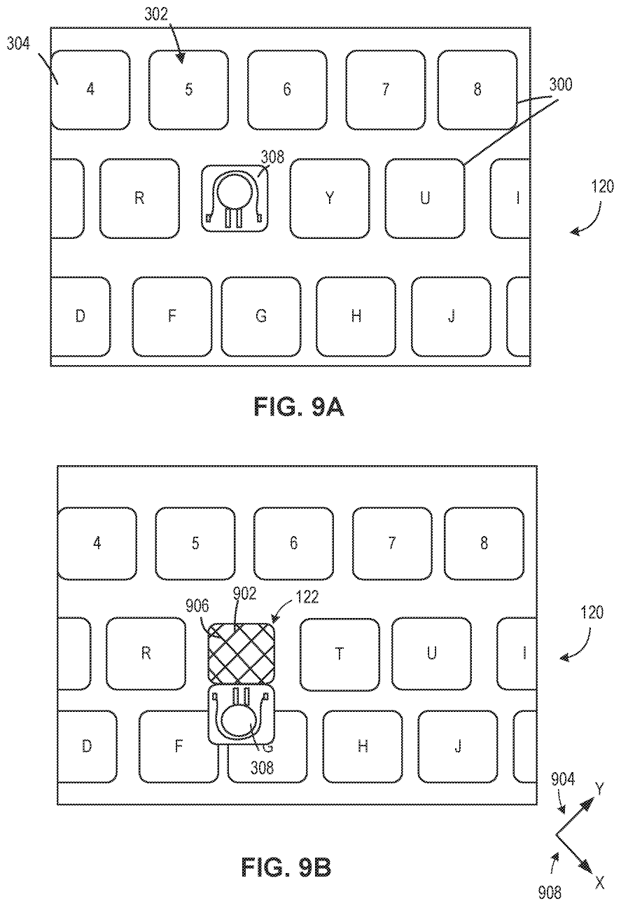

In the illustrated example of FIGS. 3A and 3B, the touch sensor 122 includes an example substrate 312, an example first layer 314, an example buffer layer 316, and an example second layer 318. The substrate 312 can be any suitable material including an insulator and/or semiconductor, such as glass, silicone, etc. The first layer 314 is a first capacitive layer that includes a first pattern of conductive material. For example, the first layer 314 can correspond to a Y-layer in which the conductive material follows a first (e.g., Y) direction. The buffer layer 316 is an insulation layer. The buffer layer 316 can be an adhesive, air, etc. The second layer 318 is a second capacitive layer that includes a second pattern of conductive material that is perpendicular to the first pattern. For example, the second layer can correspond to an X-layer in which the conductive material follows a second (e.g., X) direction. An example touch sensor 122 is illustrated in accordance with the X-axis and Y-axis in FIG. 9B. The first layer 314 and/or the second layer 318 can be made using a film (e.g., a glass film) that includes a plurality of conductive elements (e.g., electrodes) made from electrically conductive materials such as indium tin oxide (ITO), silver, copper, carbon, etc. The patterns of the electrodes can take on different shapes or construction of the pattern, such as triangles, diamonds, etc. It is understood, however, that the touch sensor 122 be structured in a variety of manners other than those disclosed herein.

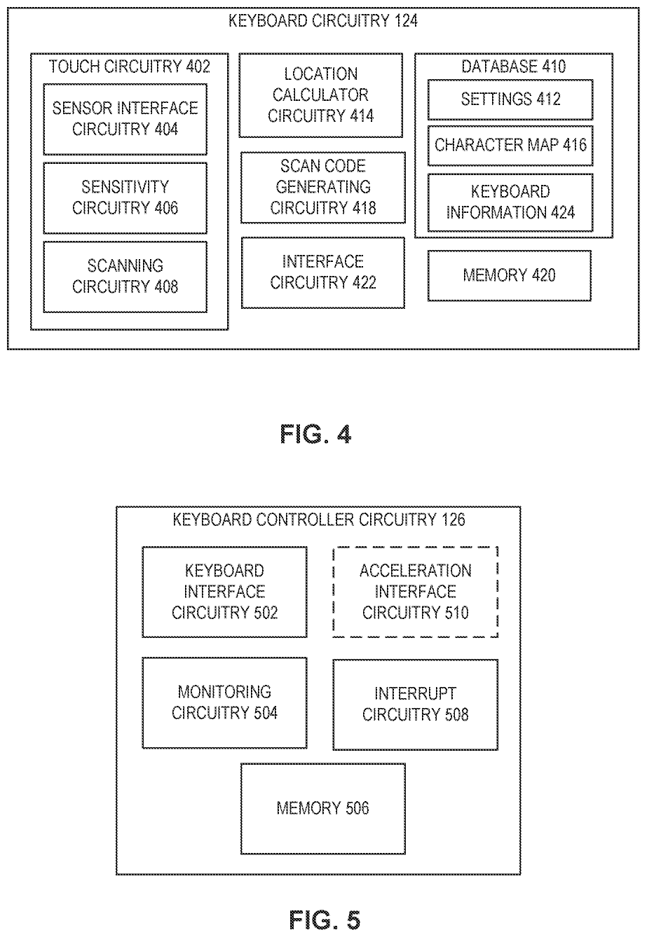

FIG. 4 is a block diagram of the example keyboard circuitry 124 of FIG. 1 to detect an input received by a user and to provide an interface between the tactile capacitive keyboard 120 and the electronic device 102. The keyboard circuitry 124 of FIG. 4 may be instantiated (e.g., creating an instance of, bring into being for any length of time, materialize, implement, etc.) by processor circuitry such as a central processing unit executing instructions. Additionally or alternatively, the keyboard circuitry 124 of FIG. 4 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 4 may, thus, be instantiated at the same or different times. Some or all of the circuitry may be instantiated, for example, in one or more threads executing concurrently on hardware and/or in series on hardware. Moreover, in some examples, some or all of the circuitry of FIG. 4 may be implemented by one or more virtual machines and/or containers executing on the microprocessor.

The keyboard circuitry 124 includes example touch circuitry 402, which structured to detect a touch event at a touch sensor (e.g., touch sensor 122). The touch circuitry 402 is also structured to interface with the touch sensor(s) 122. The touch circuitry 402 includes example sensor interface circuitry 404, example sensitivity circuitry 406, and example scanning circuitry 408. In the illustrated example of FIG. 4, the keyboard circuitry 124 includes an example database 410, which is structured to store data associated with the keyboard 120. The example database 410 of the illustrated example of FIG. 4 is implemented by any memor(ies), storage device(s) and/or storage disc(s) for storing data such as, for example, flash memory, magnetic media, optical media, etc. Furthermore, the data stored in the example database 410 may be in any data format such as, for example, binary data, comma delimited data, tab delimited data, structured query language (SQL) structures, image data, etc.

The example sensor interface circuitry 404 is structured to provide an interface between the touch sensor(s) 122 and other components of the keyboard circuitry 124 and/or the electronic device 102. The sensor interface circuitry 404 is communicatively coupled to the touch sensor(s) 122. For example, the sensor interface circuitry 404 can be coupled to example sensing elements (e.g., electrodes) of the touch sensor 122. The sensor interface circuitry 404 receives and/or retrieves a signal(s) output by the touch sensor 122. In some examples, the sensor interface circuitry 404 detects the signal(s) in response to instruction from the scanning circuitry 408.

In the illustrated example of FIG. 4, a sensitivity of the touch sensor 122 can be adjusted (e.g., programmed, set, changed, etc.). For example, the user may desire the keyboard 120 to have a first sensitivity when typing via the keyboard 120, such as when writing an email and/or other communication. The user may desire the keyboard 120 to have a second sensitivity when the user is playing a video game to reduce an operational keystroke and input a command sooner to reduce a latency. For example, the second sensitivity may be higher than the first sensitivity so that the keyboard 120 is faster to react in response to input. In some examples, the sensitivity of the touch sensor 122 implements an operational keystroke. For example, a higher sensitivity can correspond to a shorter operational keystroke and a lower sensitivity can correspond to a longer operational keystroke.

The example sensitivity circuitry 406 is structured to configure the sensitivity of the touch sensor 122. In some examples, the sensitivity circuitry 406 adjusts the sensitivity of the touch sensor 122 via the sensor interface circuitry 404. In some examples, the sensitivity circuitry 406 adjusts the sensitivity of the touch sensor 122 based on input from the user. The sensitivity can be adjusted in a variety of manners. In some examples, the sensitivity is adjusted via at least one key of the keyboard 120. For example, the keyboard 120 can be configured such that the user can execute a keystroke to adjust the sensitivity of the touch sensor 122. For example, a spacebar of the keyboard 120 can be configured to adjust the sensitivity of the keyboard 120 by enabling the user to slide a finger and/or stylus in one direction along the spacebar to increase the sensitivity and in another direction along the spacebar to decrease the sensitivity. In some examples, the user can adjust the sensitivity of the touch sensor 122 via the electronic device 102. For example, the user can utilize settings in the electronic device 102 to configure the sensitivity of the keyboard via the example keyboard controller circuitry 126 of FIG. 1. The sensitivity circuitry 406 can adjust the sensitivity of the touch sensor 122 in response to instructions from the keyboard controller circuitry 126. It is understood that the sensitivity of the touch sensor 122 can be adjusted in other manners not disclosed herein in additional or alternative examples.

As noted above, the touch sensor 122 implements a key matrix of the keyboard 120. The exampling scanning circuitry 408 is structured to periodically and/or aperiodically scan the key matrix implemented by the touch sensor 122 to detect a touch corresponding to an input. The scanning circuitry 408 may detect the touch by detecting a change in capacitance at a location of the touch at the touch sensor 122. For example, the touch sensor 122 may include multiple layers of sensing film, including a first layer of Y-direction sensing elements and a second layer of X-direction sensing elements. The scanning circuity 408 can scan along the sensing elements to detect a change in capacitance caused by a user's finger and/or an electric charge carrying component such as a stylus.

In some examples, the scanning circuitry 408 can scan the touch sensor 122 at a rate of approximately 250 Hz. The scan rate can be stored in example settings 412 stored in the database 410. In some examples, the scan rate can be adjusted by the user and/or components of the keyboard 120 and/or the electronic device 102. In some examples, the scanning circuitry 408 scans the touch sensor 122 via the sensor interface circuitry 404.

The keyboard circuitry 124 includes example location calculator circuitry 414, which is structured to determine (e.g., calculate) a location of a touch. For example, the scanning circuitry 408 may notify the location calculator circuitry 414 of a touch in response to detection of the touch during a scan. The location calculator circuitry 414 can identify an element of the key matrix with the greatest change in capacitance and calculate the touch position(s) within the layers of the touch sensor 122. For example, the greatest change in capacitance may have occurred at an intersection of an X-layer electrode and a Y-layer electrode. The location of the touch in such an example can be determined by identifying the intersection of the electrodes.

The keyboard circuitry 124 includes example scan code generating circuitry 418, which is structured to generate a scan code in response to the input touch being detected at the touch sensor 122. In some examples, the scan code generating circuitry 418 receives and/or retrieves the location of the touch from the example location calculator circuitry 414. The scan code generating circuitry 418 can then search the determined location against a character map 416 to identify a key corresponding to that location. The scan code generating circuitry 418 interprets the touch of the identified key as a keystroke for that key. In the illustrated example of FIG. 4, the scan code generating circuitry 418 generates a scan code corresponding to the identified keystroke. For example, the scan code generating circuitry 418 can convert the identified keystroke into a binary code that the electronic device 102 can understand and recognize as the respective keystroke. The scan code can be an ASCII code, a Unicode, etc.

In some examples, the scan code generating circuitry 418 stores the scan code in example memory 420. The example memory 420 is structured to store data such as scan codes obtained from the scan code generating circuitry 418. In some examples, the memory 420 may be implemented by a volatile memory (e.g., a SDRAM, a DRAM, a RDRAM), a DDR memory, such as DDR, DDR2, DDR3, DDR4, mDDR, etc.) and/or a non-volatile memory (e.g., flash memory, a HDD, etc.).

In the illustrated example of FIG. 4, the keyboard circuitry also includes interface circuitry 422, which is structured to provide an interface between the keyboard circuitry 124 and other components in communication with the keyboard 120, such as the keyboard controller circuitry 126. For example, the interface circuitry 422 is constructed to respond to requests from the keyboard controller circuitry 126. In some examples, the keyboard controller circuitry 126 can request data from the keyboard circuitry 124, such as a scan code stored in a buffer and/or keyboard information 424 corresponding to the keyboard 120. The keyboard information 424 can include, for example, a device identifier, a serial number for the tactile capacitive keyboard 120, and data regarding communication protocol(s) between the keyboard 120 and the keyboard controller circuitry 126. For example, the keyboard information 424 can include information about how the keyboard 120 is structured to report input data, such as polling rate, a scan code type, etc. so the keyboard controller circuitry 126 can properly prepare to receive this information.

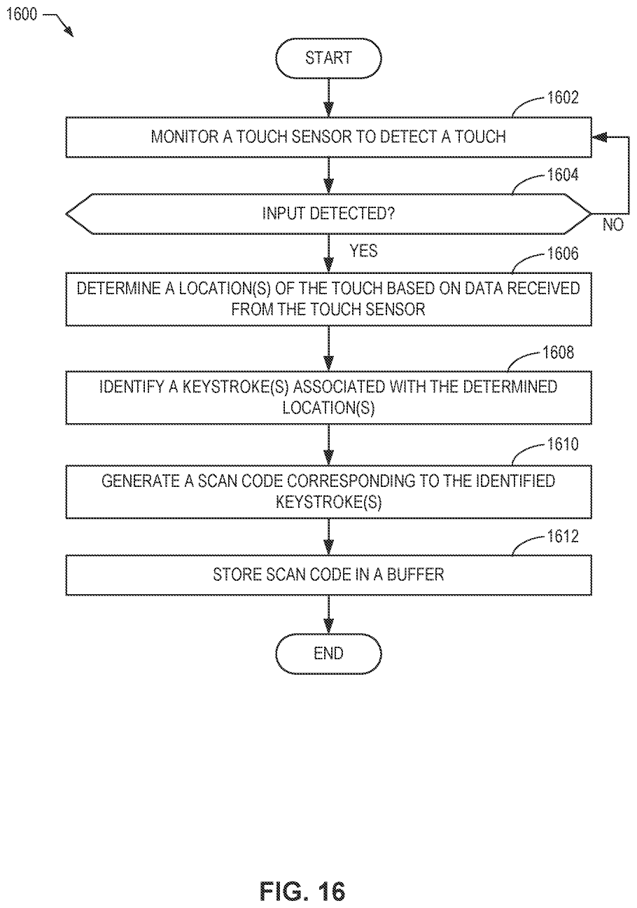

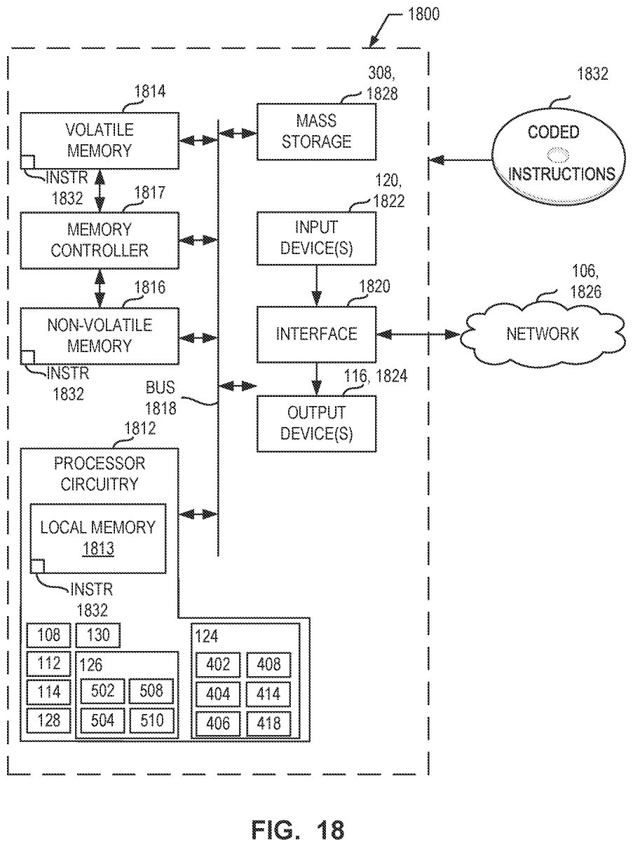

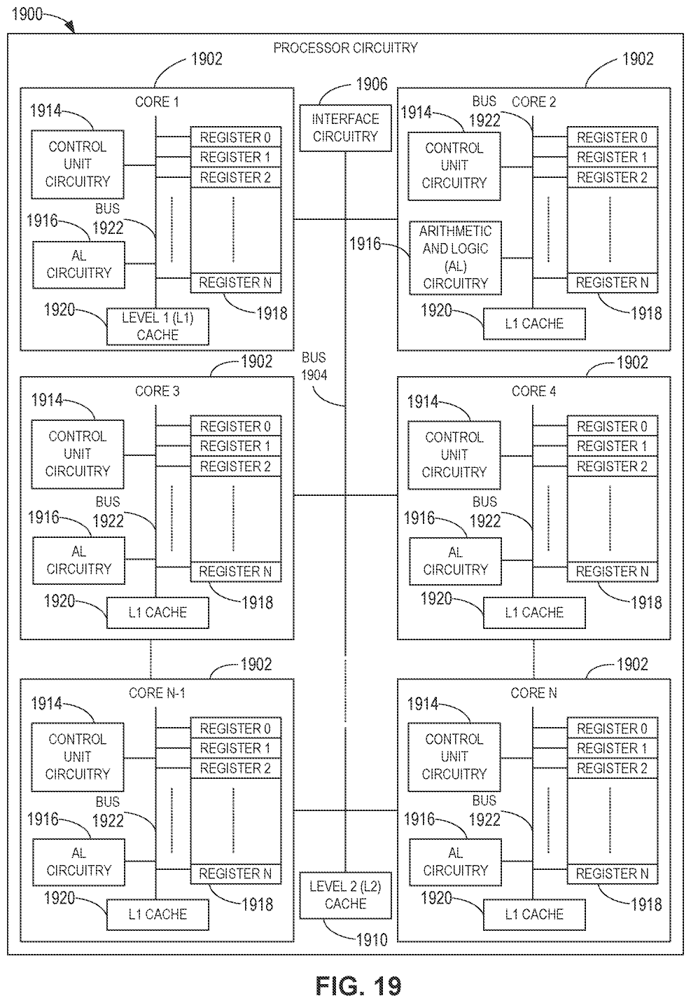

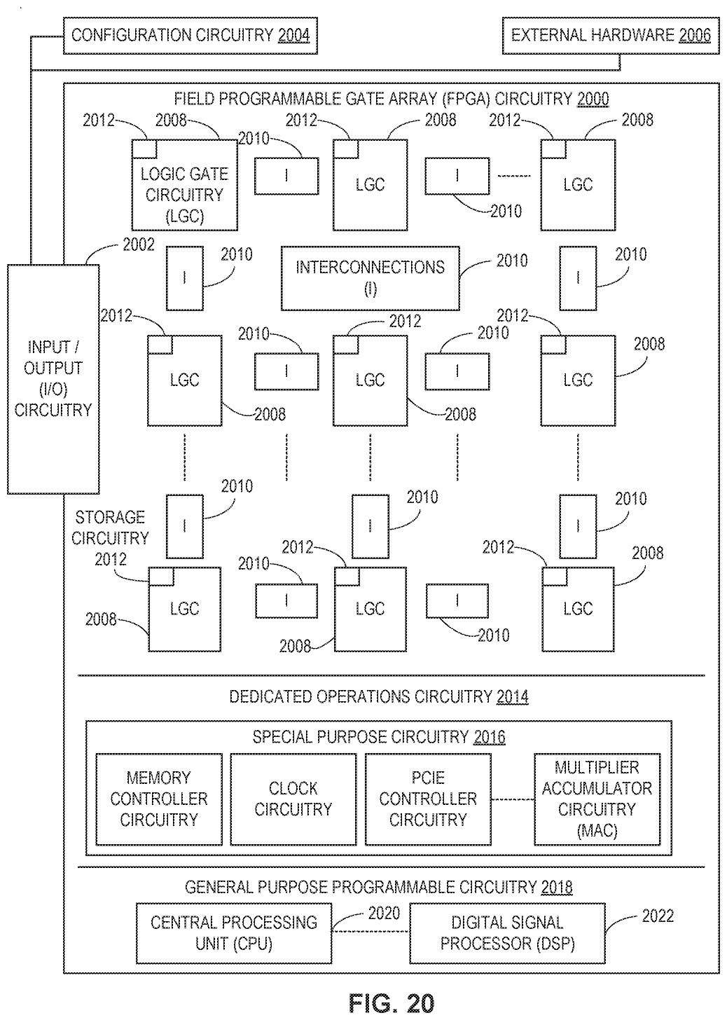

In some examples, the keyboard circuitry 124 includes means for detecting a touch. For example, the means for detecting a touch may be implemented by scanning circuitry 408. In some examples, the scanning circuitry 408 may be instantiated by processor circuitry such as the example processor circuitry 1812 of FIG. 18. For instance, the scanning circuitry 408 may be instantiated by the example general purpose processor circuitry 1900 of FIG. 19 executing machine executable instructions such as that implemented by at least blocks 1602, 1604 of FIG. 16. In some examples, the scanning circuitry 408 may be instantiated by hardware logic circuitry, which may be implemented by an ASIC or the FPGA circuitry 2000 of FIG. 20 structured to perform operations corresponding to the machine readable instructions. Additionally or alternatively, the scanning circuitry 408 may be instantiated by any other combination of hardware, software, and/or firmware. For example, the scanning circuitry 408 may be implemented by at least one or more hardware circuits (e.g., processor circuitry, discrete and/or integrated analog and/or digital circuitry, an FPGA, an ASIC, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

While an example manner of implementing the keyboard circuitry 124 of FIG. 1 is illustrated in FIG. 4, one or more of the elements, processes, and/or devices illustrated in FIG. 4 may be combined, divided, re-arranged, omitted, eliminated, and/or implemented in any other way. Further, the example touch circuitry 402, example sensor interface circuitry 404, example sensitivity circuitry 406, example scanning circuitry 408, example location calculator circuitry 414, example scan code generating circuitry 418, example interface circuitry 422, and/or, more generally, the example keyboard circuitry 124 of FIG. 1, may be implemented by hardware alone or by hardware in combination with software and/or firmware. Thus, for example, any of the example touch circuitry 402, example sensor interface circuitry 404, example sensitivity circuitry 406, example scanning circuitry 408, example location calculator circuitry 414, example scan code generating circuitry 418, example interface circuitry 422, and/or, more generally, the example keyboard circuitry 124, could be implemented by processor circuitry, analog circuit(s), digital circuit(s), logic circuit(s), programmable processor(s), programmable microcontroller(s), GPU(s), DSP(s), ASIC(s), PLD(s), and/or FPLD(s) such as FPGAs. Further still, the example keyboard circuitry 124 of FIG. 1 may include one or more elements, processes, and/or devices in addition to, or instead of, those illustrated in FIG. 4, and/or may include more than one of any or all of the illustrated elements, processes and devices.

FIG. 5 is a block diagram of the keyboard controller circuitry 126 to interface between the keyboard circuitry 124 and the electronic device 102. The keyboard controller circuitry 126 of FIG. 5 may be instantiated (e.g., creating an instance of, bring into being for any length of time, materialize, implement, etc.) by processor circuitry such as a central processing unit executing instructions. Additionally or alternatively, the keyboard controller circuitry 126 of FIG. 5 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 5 may, thus, be instantiated at the same or different times. Some or all of the circuitry may be instantiated, for example, in one or more threads executing concurrently on hardware and/or in series on hardware. Moreover, in some examples, some or all of the circuitry of FIG. 5 may be implemented by one or more virtual machines and/or containers executing on the microprocessor.

In some examples, the keyboard controller circuitry 126 implements a keyboard controller. In some examples, the keyboard controller circuitry 126 implements a keyboard driver. In some such examples, the user can adjust settings of the keyboard 120 via the keyboard controller circuitry 126 of the electronic device 102. For example, the user can adjust the sensitivity of the keyboard's 120 touch sensor(s) 122 in some examples.

The keyboard controller circuitry 126 includes example keyboard interface circuitry 502, which is structured to provide an interface between the keyboard circuitry 124 and the keyboard controller circuitry 126 and/or other components of the electronic device 102. In some examples, the keyboard controller circuitry 126 can adjust settings of the tactile capacitive keyboard 120 via the keyboard interface circuitry 502. In some examples, the keyboard controller circuitry 126 can request information from the keyboard circuitry 124 via the keyboard interface circuitry 502, such keyboard information 424.

The keyboard controller circuitry 126 includes example monitoring circuitry 504, which is structured to periodically and/or aperiodically poll the keyboard circuitry 124 to determine whether input was received at the keyboard 120. For example, the monitoring circuitry 504 can query the keyboard circuitry 124 as to whether a scan code corresponding to a keystroke (e.g., an input received at the tactile capacitive keyboard 120) is available. In some examples, the monitoring circuitry 504 sends a signal such as a token to the keyboard circuitry 124 to request a scan code that is available for processing. In some examples, the monitoring circuitry 504 polls the keyboard circuitry 124 at a polling rate of 1,000 Hz. In other examples, other polling rates may be used. If the keyboard circuitry 124 includes a scan code stored in the memory 420, the keyboard circuitry 124 can respond by transmitting the scan code to the monitoring circuitry 504.

In some examples, the keyboard controller circuitry 126 includes example memory 506, which is structured to store data received from the keyboard circuitry 124, such as keyboard information 424, scan codes, etc. In some examples, the memory 506 can be one or more memory systems that include various types of computer memory. In some examples, the memory 506 may be implemented by a volatile memory (e.g., a SDRAM, a DRAM, a RDRAM, a DDR memory, such as DDR, DDR2, DDR3, DDR4, mDDR, etc.) and/or a non-volatile memory (e.g., flash memory, a HDD, etc.).

The keyboard controller circuitry 126 includes example interrupt circuitry 508. In response to the monitoring circuitry 504 detecting the input received at the keyboard 120, the keyboard controller circuitry 126 can instruct the interrupt circuitry 508 to generate an interrupt. The example interrupt circuitry 508 can generate and transmit an interrupt request to a processor to notify the processor that the scan code needs to be processed. In some examples, the interrupt circuitry 508 sends the interrupt request to processing circuitry of the electronic device 102, such a processor circuitry 108 and/or other processing circuitry.

In some examples, the electronic device 102 includes example acceleration circuitry 130. In some such examples, the acceleration circuitry 130 implements an example hardware accelerator that is configured to process input received via the tactile capacitive keyboard 120. Thus, in some examples, the keyboard controller circuitry 126 includes example acceleration interface circuitry 510, which is structured to provide an interface between the keyboard controller circuitry 126 and the acceleration circuitry 130. In response to the monitoring circuitry 504 receiving the scan code from the keyboard circuitry 124, the keyboard controller circuitry 126 can send the scan code directly to the acceleration circuitry 130 for processing. In some examples, the interrupt circuitry 508 sends an interrupt request to the acceleration circuitry 130.

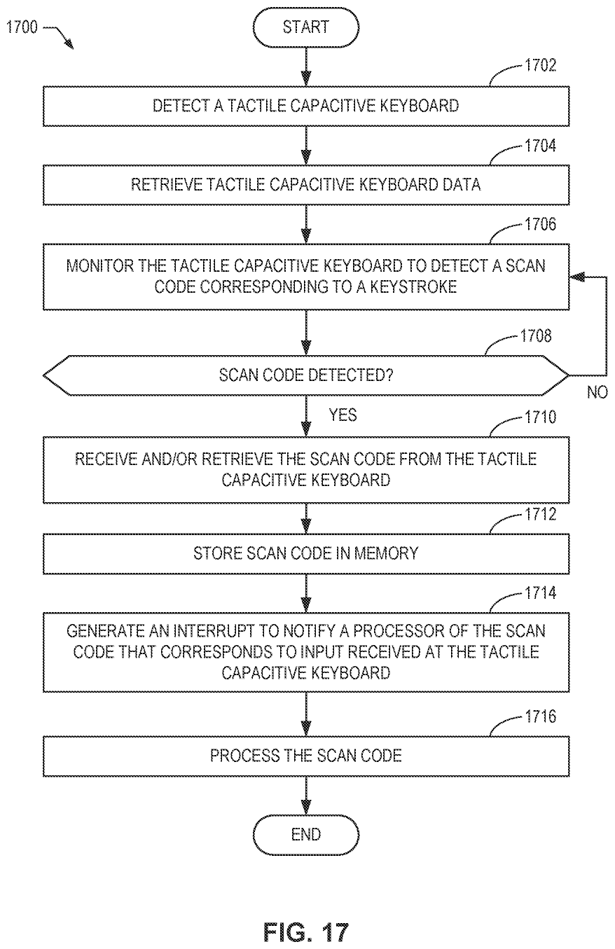

In some examples, the keyboard controller circuitry 126 includes means for obtaining a scan code from the tactile capacitive keyboard 120. For example, the means for obtaining the scan code may be implemented by monitoring circuitry 504. In some examples, the monitoring circuitry 504 may be instantiated by processor circuitry such as the example processor circuitry 1812 of FIG. 18. For instance, the monitoring circuitry 504 may be instantiated by the example general purpose processor circuitry 1900 of FIG. 19 executing machine executable instructions such as that implemented by at least blocks 1706-1712 of FIG. 17. In some examples, the monitoring circuitry 504 may be instantiated by hardware logic circuitry, which may be implemented by an ASIC or the FPGA circuitry 2000 of FIG. 20 structured to perform operations corresponding to the machine readable instructions. Additionally or alternatively, the monitoring circuitry 504 may be instantiated by any other combination of hardware, software, and/or firmware. For example, the monitoring circuitry 504 may be implemented by at least one or more hardware circuits (e.g., processor circuitry, discrete and/or integrated analog and/or digital circuitry, an FPGA, an ASIC, a comparator, an op-amp, a logic circuit, etc.) structured to execute some or all of the machine readable instructions and/or to perform some or all of the operations corresponding to the machine readable instructions without executing software or firmware, but other structures are likewise appropriate.

While an example manner of implementing the keyboard controller circuitry 126 of FIG. 1 is illustrated in FIG. 5, one or more of the elements, processes, and/or devices illustrated in FIG. 5 may be combined, divided, re-arranged, omitted, eliminated, and/or implemented in any other way. Further, the example keyboard interface circuitry 502, example monitoring circuitry 504, example interrupt circuitry 508, example acceleration interface circuitry 510, and/or, more generally, the example keyboard controller circuitry 126 of FIG. 1, may be implemented by hardware alone or by hardware in combination with software and/or firmware. Thus, for example, any of the example keyboard interface circuitry 502, example monitoring circuitry 504, example interrupt circuitry 508, example acceleration interface circuitry 510, and/or, more generally, the example keyboard controller circuitry 126, could be implemented by processor circuitry, analog circuit(s), digital circuit(s), logic circuit(s), programmable processor(s), programmable microcontroller(s), GPU(s), DSP(s)), ASIC(s), PLD(s) and/or FPLD(s) such as FPGAs. Further still, the example keyboard controller circuitry 126 of FIG. 1 may include one or more elements, processes, and/or devices in addition to, or instead of, those illustrated in FIG. 5, and/or may include more than one of any or all of the illustrated elements, processes and devices.

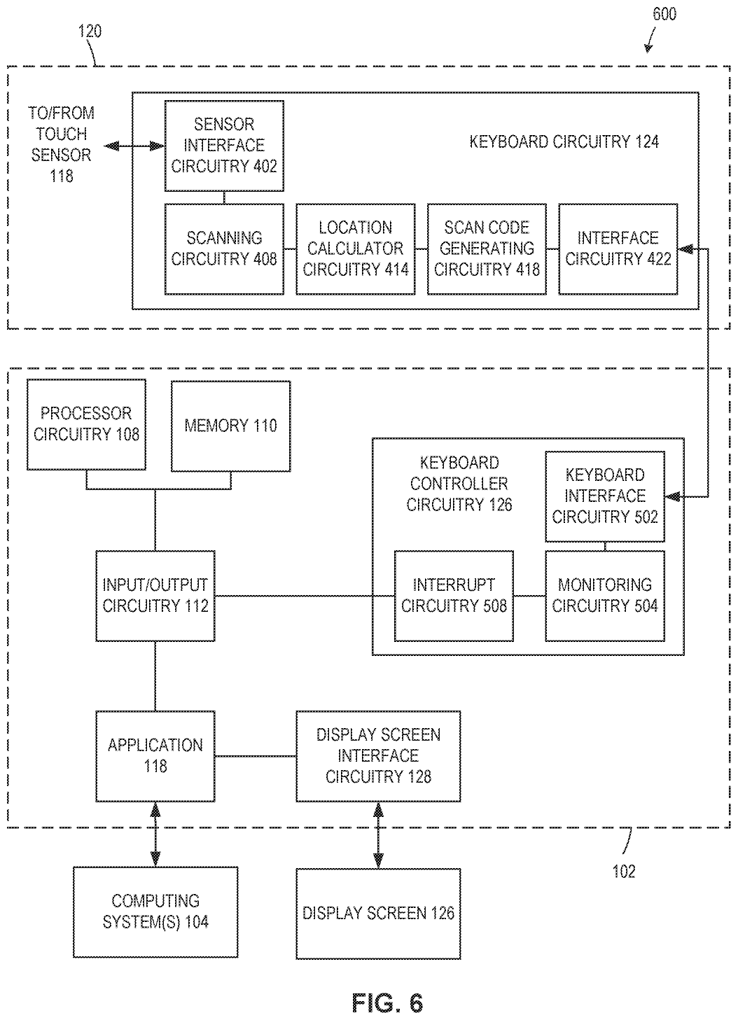

FIG. 6 is a block diagram of an example framework 600 for implementing the example system 100 of FIG. 1 to process an input received via the example tactile capacitive keyboard 120, including example implementations of the example keyboard circuitry 124 and the example keyboard controller circuitry 126. During operation of the electronic device 102, the scanning circuitry 408 periodically scans the touch sensor 122 via the sensor interface circuitry 404. In some examples, the scanning circuitry 408 scans the touch sensor 122 to identify a change in capacitance at a location of the touch sensor 122. In response to detecting such a change in capacitance, the scanning circuitry 408 notifies the example location calculator circuitry 414.

In the illustrated example of FIG. 6, the location calculator circuitry 414 determines the location of the change of capacitance. The location calculator circuitry 414 can then send the determined location to the scan code generating circuitry 418. The scan code generating circuitry 418 compares the determined location to a character map stored in the database to identify a key corresponding to that location. The scan code generating circuitry 418 interprets the change in capacitance at that area as a keystroke for the corresponding key. The scan code generating circuitry 418 converts the keystroke to a code (e.g., scan code) that the electronic device 102 can understand. The scan code generating circuitry 418 can store the scan code in example memory 420 until the scan code is transmitted to example keyboard controller circuitry 126.

The example monitoring circuitry 504 of the example keyboard controller circuitry 126 periodically polls the tactile capacitive keyboard 120 via the keyboard interface circuitry 502 to determine whether a scan code is available for processing. For example, the monitoring circuitry 504 sends a request to example interface circuitry 422 of the keyboard circuitry 124 asking whether a scan code is available for processing. If a scan code is stored in a buffer in the memory 410, the interface circuitry 422 replies to the request by notifying the monitoring circuitry 504 of the scan code. Further, the interface circuitry 422 sends the scan code to the monitoring circuitry 504. In some examples, the monitoring circuitry 504 stores the scan code in example memory 506 and notifies the interrupt circuitry 508.

In the illustrated example of FIG. 6, the interrupt circuitry 508 generates an interrupt request to example processor circuitry 108 and transmits the request to example input/output circuitry 112, which implements an interrupt handler. The input/output circuitry 112 notifies the processor circuitry 108 of the interrupt request. When the processor circuitry 108 is ready, the processor circuitry 108 notifies the input/output circuitry 112 and requests the scan code. The processor circuitry 108 receives the scan code, identifies a keystroke corresponding to the scan code, and processes the scan code accordingly. For example, the processor circuitry 108 determines whether the keystroke is a command, such as a system command. In response to determining the keystroke is a command, the processor circuitry 108 executes the command. In response to determining the keystroke is not a command, the processor circuitry 108 transmits the keystroke to an application 118 awaiting the keystroke (e.g., via the input/output circuitry 112).

When the keystroke is not a command, the application 118 receives the keystroke and responds accordingly. For example, if the application 118 is a word processor, the application 118 may input a letter and/or number into the word processor document. If the application 118 is a video game, the application 118 may process the keystroke and cause a character in the video game to respond accordingly. The application 118 sends the effect of the keystroke to the display screen controller circuitry 128, which causes effect to be rendered on the display screen 116. The application can also send the effect of the keystroke to another computing system 104 (e.g., via the network 106) to be displayed on the other computing system 104.

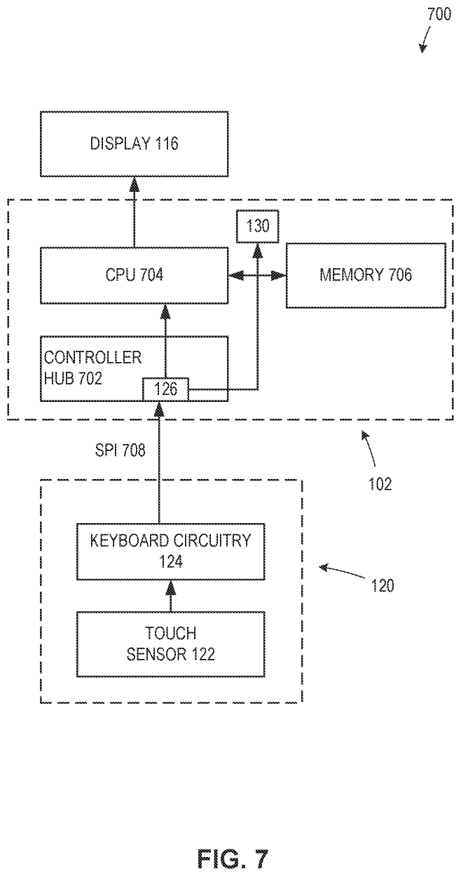

FIG. 7 illustrates an example environment 700 to report and process input received at an example tactile capacitive keyboard (e.g., tactile capacitive keyboard 120, including example keyboard controller circuitry (e.g., keyboard controller circuitry 126). FIG. 7 illustrates a latency reduction as compared to a processing environments of known, mechanical keyboards, which suffer keystroke latency due to long travel distances required for an operational keystroke, debouncing latency, polling latency, reporting latency, and interpret processing latency.

As described above, the tactile capacitive keyboard 120 results in a reduced latency by reducing an operational keystroke. The operational keystroke is reduced by integrating a touch sensor 122 below a key(s) to implement a key matrix. Further, by integrating the touch sensor 122 to detect a keystroke, the keystroke results in little to no vibrations that cause bouncing. Accordingly, the tactile capacitive keyboard 120 reduces keystroke latency and debouncing latency.

The environment 700 of FIG. 7 includes an example controller hub 702, an example CPU 704, and an example memory 706. The controller hub 702 can implement a chipset of the electronic device 102. The controller hub 702 includes a plurality of controllers and drivers corresponding to a plurality of peripheral devices. In some examples, the controller hub 702 manages polling functions, data transmission, interrupt requests, etc. for the plurality of peripheral devices.

A conventional mechanical keyboard typically communicates with a respective controller of a controller hub via a controller hub interface. An embedded controller within the conventional mechanical keyboard can transmit a scan code to the respective controller of the controller hub via the controller hub interface. However, because the controller hub manages the plurality of peripheral device, utilizing the embedded controller and the controller hub to implement the conventional keyboard results in a polling latency and a reporting latency.

The controller hub 702 of FIG. 7 includes example keyboard controller circuitry (e.g., the keyboard controller circuitry 126). Further, the environment 700 includes an example serial peripheral interface 708 positioned between the keyboard controller circuitry 126 and the keyboard circuitry 124. The SPI 708 is a dedicated interface between the keyboard controller circuitry 126 and the keyboard circuitry 124. The SPI 708 may be implemented by example keyboard interface circuitry (e.g., keyboard interface circuitry 502). By integrating the dedicated SPI 708, the keyboard controller circuitry 126 and the keyboard circuitry 124 can interact directly rather than through the controller hub 702. For example, the keyboard controller circuitry 126 can directly poll the keyboard circuitry 124. Further, the keyboard circuitry 124 can transmit a scan code directly to the keyboard controller circuitry 126. Accordingly, the environment 700 results in reduced polling latency and a reporting latency.

In some examples, the keyboard controller circuitry 726 generates an interrupt to the CPU 704 notifying the CPU 704 of a scan code that needs processing. In some examples, the CPU 704 decides to process the scan code at an appropriate time. Numerous factors are considered in decisions of when to process the scan code. For example, the CPU 704 typically processes most of data that is received at the electronic device 102. Thus, the CPU 704 often receives numerous interrupts. At the desired time, the CPU 704 processes the scan code by reading the scan code and responding accordingly. Accordingly, examples in which the keyboard controller circuitry 726 sends the interrupt to the CPU 704 to process the scan code results in a processing latency corresponding to processing the scan code.

However, the electronic device 102 of FIG. 7 includes example acceleration circuitry 130, which is structured to implement an example accelerator. Once the keyboard controller circuitry 126 receives a scan code from the keyboard circuitry 124, the keyboard controller circuitry 126 can report the scan code to the acceleration circuitry 130. Accordingly, the keyboard controller circuitry 126 does not have to transmit an interrupt request to the CPU 704 and/or wait for the CPU 704 to be ready to process the scan code. Rather, the acceleration circuitry 130 can process the scan code. Accordingly, the keyboard controller circuitry 126 and the acceleration circuitry 130 reduce a processing latency corresponding to processing the scan code.

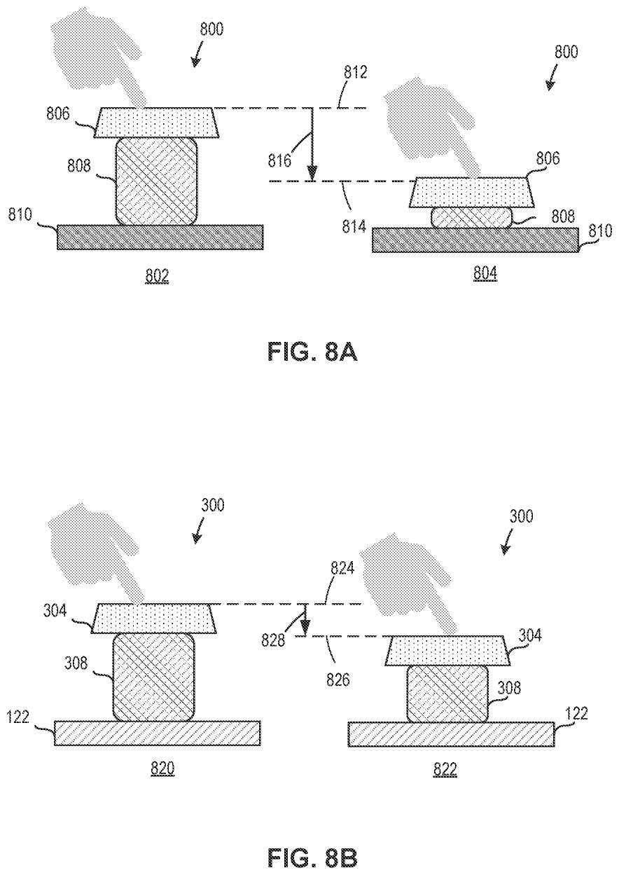

FIGS. 8A and 8B illustrate example operational keystrokes of a conventional keyboard and an example tactile capacitive keyboard, such as the example tactile capacitive keyboard 120 of FIG. 1, respectively. FIG. 8A is a partial, schematic illustration of the example conventional keyboard, including an example key 800 in a resting position 802 and a depressed position 804. The key 800 includes a keycap 806, an example rubber dome 808, and an example key matrix 810 that includes a grid of circuits, including a circuit below the key 800. In the resting position 802, the keycap 806 is at a first position 812 and the rubber dome 808 is at rest. In the depressed position 804, the keycap 806 is at a second position 814 and the rubber dome 808 is depressed, which enables a switch (not shown in FIG. 8A) to close the key's circuit within the key matrix 810. The operational keystroke 816 is a distance traveled by the keycap from the first position 812 to the second position 814. The operational keystroke 816 is a minimum distance the key 800 must travel to close the circuit and register the movement as a keystroke. In some examples, the key 800 is able to travel further down. However, the key 800 cannot travel a lesser distance and still register as a keystroke.

FIG. 8B is a partial, schematic illustration of an example tactile capacitive keyboard 120, including an example (e.g., key 300) in a resting position 820 and a depressed position 822. FIG. 8B illustrates how the tactile capacitive keyboard 120 shortens an operational keystroke. The key 300 includes a keycap 304, an example rubber dome 308, and an example touch sensor 122, which implements a key matrix. In the resting position 820, the keycap 304 is at a first position 824 and the rubber dome 308 is at rest in an extended state. In the depressed position 822, the keycap 304 is at a second position 826 and the rubber dome 308 is depressed in a contracted or compressed state. The operational keystroke 828 is a distance traveled by the keycap 304 from the first position 824 to the second position 826. In the illustrated example of FIG. 8B, the operational keystroke 828 is less than the operation keystroke 816 of the conventional keyboard of FIG. 8A.

In some examples, the operational keystroke 828 of the tactile capacitive keyboard 120 is adjustable. The more sensitive the touch sensor 122 is to detect a change in capacitance, the less the key 300 needs to be pressed to register a keystroke. In some examples, the touch sensor 122 can be programmed to increase and/or decrease a sensitivity of the touch sensor 122. By increasing the sensitivity of the touch sensor 122, the operational keystroke 828 can be shortened even further. Accordingly, in some examples, the operational keystroke 828 can be programmed by adjusting the sensitivity of the touch sensor 122. In some examples, the sensitivity of the touch sensor 122 can be adjusted such that the user does not have to touch the key 300 to register an input. In other words, the keyboard 122 has hovering-enabled operational keystrokes. In some such examples, the operational keystroke 828 is zero and/or less than zero. For example, the operational keystroke 828 can be a distance a finger must be above (e.g., away from) the keycap 304 to detect the change in capacitance.

FIGS. 9A and 9B are a partial views of an example tactile capacitive keyboard (e.g., tactile capacitive keyboard 120 of FIG. 1), including a plurality of example keys (e.g., key(s) 300 of FIG. 3). The keys 300 include corresponding key identifiers 302 on respective keycaps 304. FIG. 9A illustrates an example key 300 that corresponds to a T key 300, with the keycap 304 removed. As illustrated in FIG. 9A, an example rubber dome 308 is positioned beneath the keycap 304.

FIG. 9B illustrates the T key 300 with the rubber dome enclosure 308 removed. As illustrated in FIG. 9B, an example touch sensor (e.g., touch sensor 122) is positioned below the example rubber dome 308 enclosure. The touch sensor 122 includes a first layer (e.g., first layer 314) of conductive material that includes rows 902 of electrodes that follow a Y-direction 904 and a second layer (e.g., second layer 318) of conductive material that includes columns 906 of electrodes that follow an X-direction 908. When a user touches and/or approaches the touch sensor 122, the location of the touch and/or proximate touch can be determined by identifying a cross-section of a row 902 and column 904 that experiences the greatest change in capacitance.

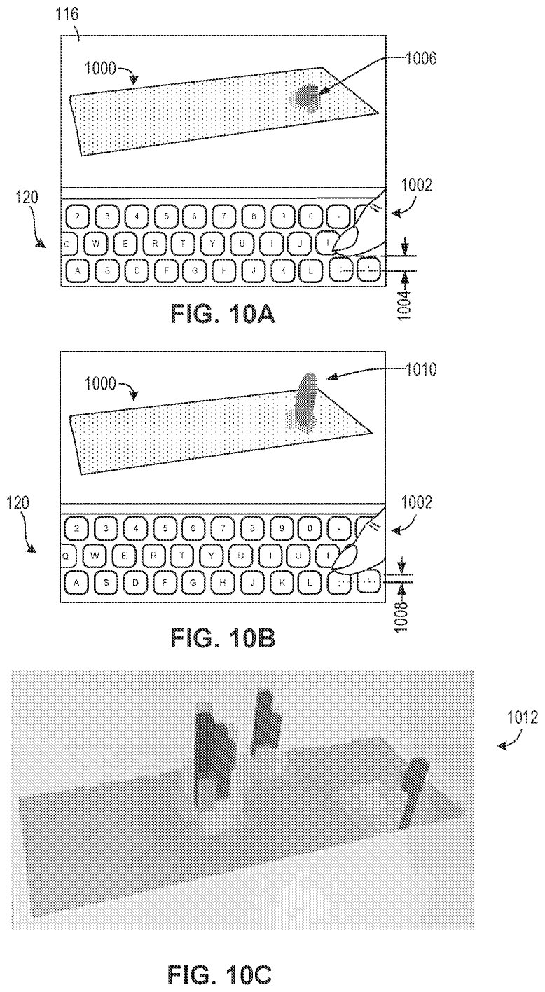

FIGS. 10A and 10B are a partial schematic illustrations of the example tactile capacitive keyboard 120 and display screen 116. The tactile capacitive keyboard 120 and display screen 116 may be components of an electronic device 102, which may be a laptop. FIG. 10A includes an example graph 1000 rendered on the display screen 116. The graph 1000 corresponds to a proximate touch of a user's finger 1002 as sensed by a touch sensor 122 (below the keys, not illustrated in FIG. 10A).

FIG. 10A illustrates the user's finger 1002 at a first distance 1004 above a keycap (e.g., keycap 304). At the first distance 1004, the graph 1000 illustrates a capacitance reading 1006 as detected by the touch sensor 122. As illustrated in FIG. 10A, the capacitance 1006 can be read via air, even before the finger 1002 touches the keycap 304.

FIG. 10B illustrates the user's finger 1002 at a second distance 1008 above the keycap 304. The second distance 1008 is less than the first distance 1004 of FIG. 10A. At the second distance 1008, the graph 1000 illustrates a second capacitance reading 1010 as detected by the touch sensor 122. As illustrated in FIG. 10B, the capacitance 1010 is even stronger than the first capacitance 1006.

FIG. 10C illustrates another graph 1012 that is reading a capacitance sensed by the example touch sensor 122 of the example tactile capacitive keyboard 120. FIG. 10C illustrates a multi-finger capacitance that can be read in real-time through example keycap (e.g., keycap(s) 304). In other words, the tactile capacitive keyboard 120 can register more than one keystroke at a time. Such features can be useful during a simulation usage of an electronic device 102. For example, some video games have multiple inputs to be received at once to initiate a specific move, command, or combinations of moves and/or commands.

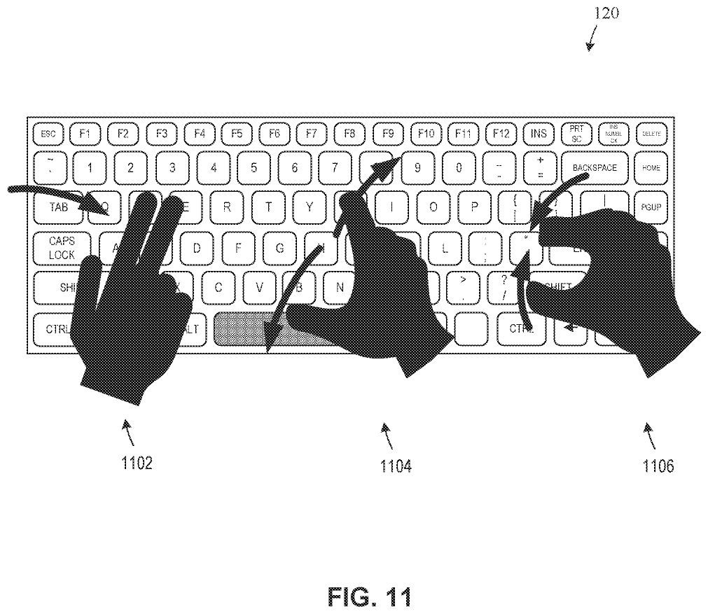

FIG. 11 illustrates example gestures that a user can program into the example tactile capacitive keyboard 120 as gesture controls. A first example gesture 1102 can be programmed to allow the user to scroll around (e.g., up, down, left, right, etc.) on an application window. A second example gesture 1104 can be programmed to allow the user to zoom in on the application window. A third example gesture 1106 can allow the user to zoom out of the application. It is understood that the example gestures 1102, 1104, 1106 are example implementations. Additional and/or alternative gestures can be programmed into the example tactile capacitive keyboard 120 in additional or alternative examples. As detailed herein, in some examples, the tactile capacitive keyboard 120 senses these gestures as the user makes the gestures within a range above the tactile capacitive keyboard 120 and without the user physically contacting keys of the tactile capacitive keyboard 120.

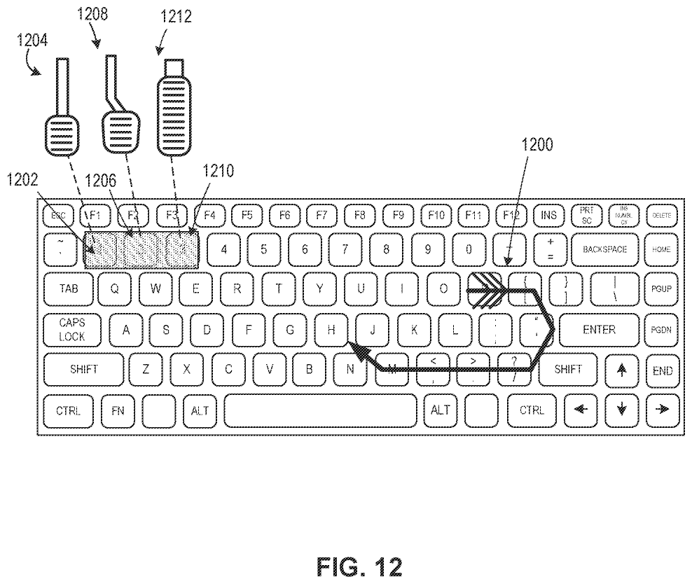

FIG. 12 illustrates other example gestures that a user can program into the example tactile capacitive keyboard 120 as gesture controls. For example, the gestures can be programmed to be specific to a specific application. For example, a character map can be stored on the electronic device 102 that overrides a default character map stored on the tactile capacitive keyboard 120. Thus, when a user gestures over a series of keys of the tactile capacitive keyboard 120 in a sequence as mapped or programmed to a command, the electronic device 102 processes the associated command.

In the illustrated example of FIG. 12, an example gesture 1200 can be programmed as an unlock gesture to unlock the electronic device 102. For example, the user may be able to log into the electronic device 102 by performing the unlock gesture 1200 instead of typing a password and/or using image recognition. This can be a great benefit for numerous users, such as for example a user with electronic devices 102 that do not include a camera for image recognition, a user who prefers not to utilize image recognition, a user whose face is covered, etc.

FIG. 12 also illustrates example gestures that can be programmed as analog input (e.g., for a video game). For example, specific keys can be programmed to be specific input for the video game. In the illustrated example of FIG. 12, a first key 1202 may correspond to a first input command 1204. The first input command 1204 can be, for example, a clutch associated with a car being driven in the video game. A second key 1206 may correspond to a second input command 1208. The second input command 1208 can be, for example, a gas pedal associated with the car being driven in the video game. A third key 1210 may correspond to a third input command 1212. The third input command 1212 can be, for example, a brake pedal associated with the car being driven in the video game. Accordingly, the user could execute keystrokes of the first key 1202, the second key 1206, and/or the third key 1210 to execute a clutch 1204, gas pedal 1208, and/or brake pedal 1212 of the car, respectively. In some examples, one key may be programmed to execute multiple commands at once or in sequence.

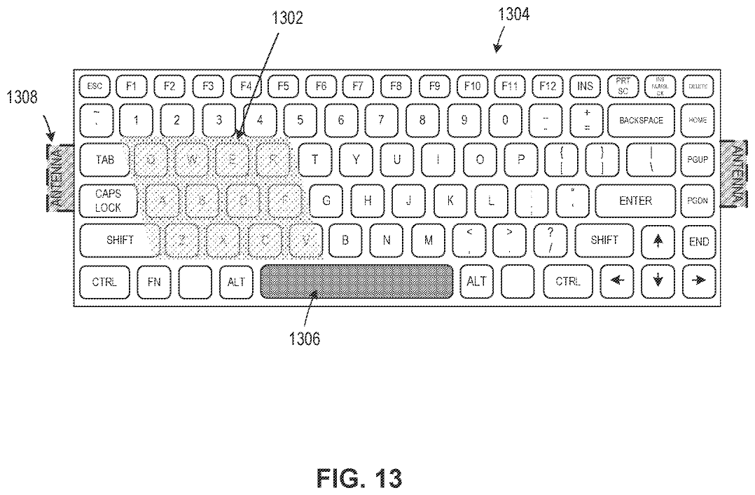

FIG. 13 illustrates an example implementation of the example tactile capacitive keyboard 120 of FIG. 1. In the illustrated example of FIG. 13, a first plurality of keys 1302 less than all example keys of the tactile capacitive keyboard 120 include a touch sensor 122 below the keys. The first plurality of keys 1302 can be low-latency keys with adjustable sensitivity. A second plurality of keys 1304 that includes at least some keys of the keyboard except the first plurality of keys 1302 can operate similar to a conventional mechanical keyboard and/or in any other manner. Accordingly, the second plurality of keys 1304 would not require an electric charge carrying component, such as a finger or stylus, to execute a keystroke. Thus, the second plurality of keys 1304 could be operated using a foreign object such as a glove, fingernail, etc.

In other examples, the second plurality of keys 1304 also include a touch sensor 122 (or multiple touch sensors 122) below the keys. In some examples, the first plurality of keys 1302 have a first sensitivity and the second plurality of keys 1304 have a second sensitivity. In some examples, the second sensitivity is different than the first sensitivity. In some examples, the second sensitivity is less than the first sensitivity. In such examples, the user can input or otherwise effect commands more quickly with the first plurality of keys 1302.

The tactile capacitive keyboard 120 of FIG. 13 includes an example space bar 1306 that includes a touch sensor 122. The space bar 1306 is programmed to include sliding gesture control(s). For example, the user can program the space bar to increase and/or decrease a volume, brightness, etc. by sliding the user's finger across (on or above) the spacebar 1306.

The keyboard 120 of FIG. 13 also includes example antennas 1308. For example, the antennas 1308 can enable the keyboard 120 to wirelessly connect to an electronic device (e.g., electronic device 102). For example, tactile capacitive keyboard 120 of FIG. 13 may include Bluetooth connectivity. As such, the tactile capacitive keyboard 120 of FIG. 13 can send and/or received signals (e.g., data) to and/or from the electronic device 102 using the antennas 1308.

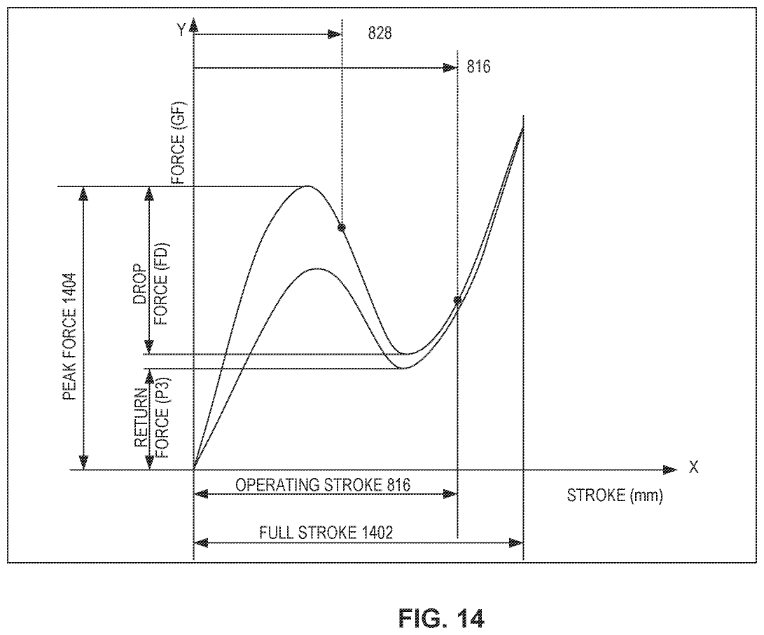

FIG. 14 is an example graph 1400 to illustrate that a feel of the tactile capacitive keyboard 120 can be configured to feel like a conventional mechanical keyboard. By integrating at least some mechanical components of the conventional mechanical keyboard, such as a keycap, movement mechanism, rubber dome, etc., the tactile capacitive keyboard 120 maintains the same tactile feeling of the conventional mechanical keyboard. For example, the graph 1400 illustrates a Y axis that corresponds to a force (GF) applied to a keycap (e.g., keycap 304). The X axis corresponds to an operational keystroke distance of the keycap 304 in millimeters (mm). The graph 1400 includes a full keystroke 1402 of a conventional keyboard and/or the tactile capacitive keyboard 120. The graph 1400 also includes an operational keystroke 816 of the conventional keyboard and an operational keystroke 828 of the tactile capacitive keyboard 120.

A peak force 1404 as illustrated in the graph 1400 corresponds to the peak force 1404 of the conventional mechanical keyboard and the tactile capacitive keyboard 120. As illustrated in FIG. 14, the operational keystroke 828 of the tactile capacitive keyboard 120 occurs after the peak force 1404, similar to the operational keystroke 816 of the conventional mechanical keyboard. However, the operational keystroke 828 of the tactile capacitive keyboard 120 occurs sooner than the conventional mechanical keyboard's operational keystroke 816. Accordingly, the operational keystroke 828 of the tactile capacitive keyboard 120 is shorter than the operational keystroke 816 of the conventional mechanical keyboard. However, the tactile capacitive keyboard 120 retains a similar tactile feeling as the conventional mechanical keyboard.

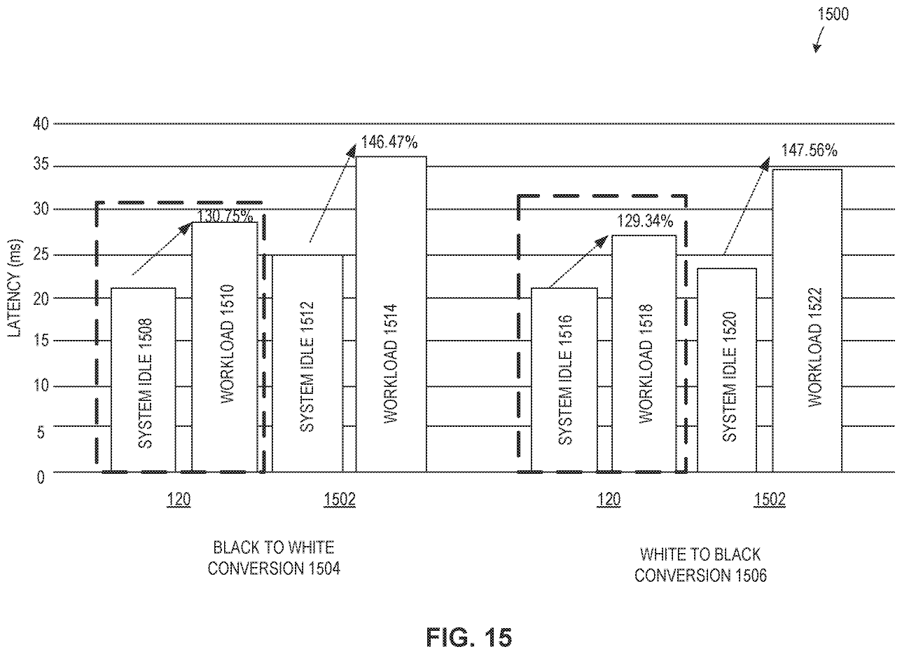

FIG. 15 is a graph 1500 illustrating example latency(ies) associated with an example tactile capacitive keyboard (e.g., tactile capacitive keyboard 120) structured in accordance with the teachings of this disclosure and an example optical keyboard 1502. The graph 1500 illustrates example measurements of latencies that include a workload (e.g., a CPU/GPU workload) and example measurements of latencies in which a system is idle. The example measurements correspond to respective response times of a display screen shifting from black pixels to white pixels 1504 and from white pixels to black pixels 1506.

First latencies associated with the black to white conversion 1504 are illustrated. A first measured latency 1508 that corresponds to the tactile capacitive keyboard 120 with the system idle is approximately 21 ms. A second measure latency 1510 that corresponds to the tactile capacitive keyboard 120 with a workload is approximately 29 ms. A third measured latency 1512 that corresponds to the optical keyboard 1502 with the system idle is approximately 25 ms. A fourth measure latency 1514 that corresponds to the optical keyboard 1502 with a workload is approximately 36 ms.

Second latencies associated with the white to black conversion 1506 are also illustrated. A first measured latency 1516 that corresponds to the tactile capacitive keyboard 120 with the system idle is approximately 21 ms. A second measure latency 1518 that corresponds to the tactile capacitive keyboard 120 with a workload is approximately 28 ms. A third measured latency 1520 that corresponds to the optical keyboard 1502 with the system idle is approximately 23 ms. A fourth measure latency 1522 that corresponds to the optical keyboard 1502 with a workload is approximately 35 ms.

Based on the foregoing, the tactile capacitive keyboard 120 as disclosed herein results in reduced latency as compared to the optical keyboard 1502 when the systems are in both idle modes and with workloads executing. Accordingly, example tactile capacitive keyboards 120 disclosed herein is more responsive that optical keyboards 1502. In other words, the tactile capacitive keyboard 120 as disclosed herein consistently outperforms the example optical keyboard 1502.

Flowcharts representative of example hardware logic circuitry, machine readable instructions, hardware implemented state machines, and/or any combination thereof for implementing the keyboard circuitry 124 of FIG. 4 and the keyboard controller circuitry 126 are shown in FIGS. 16 and 17, respectively. The machine readable instructions may be one or more executable programs or portion(s) of an executable program for execution by processor circuitry, such as the processor circuitry 1812 shown in the example processor platform 1800 discussed below in connection with FIG. 18 and/or the example processor circuitry discussed below in connection with FIGS. 19 and/or 20. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowcharts illustrated in FIGS. 16-17, many other methods of implementing the example keyboard circuitry 124 and/or keyboard controller circuitry 126 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU), etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 16 and/or 17 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium and non-transitory computer readable storage medium are expressly defined to include any type of computer readable storage device and/or storage disk and to exclude propagating signals and to exclude transmission media.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 16 is a flowchart representative of example machine readable instructions and/or example operations 1600 that may be executed and/or instantiated by processor circuitry to receive an input via an example tactile capacitive keyboard (e.g., tactile capacitive keyboard 120). The machine readable instructions and/or the operations 1600 of FIG. 16 begin at block 1602, at which the example scanning circuitry 408 monitors an example touch sensor(s) (e.g., touch sensor(s) 122) to detect a touch (including a hovering of a finger or stylus, etc.) corresponding to an input. The scanning circuitry 408 can monitor the touch sensor 122 via example sensor interface circuitry (e.g., sensor interface circuitry 404). The scanning circuitry 408 may monitor the touch sensor 122 by periodically and/or aperiodically scanning a key matrix corresponding to the touch sensor 122. For example, the touch sensor 122 may include multiple layers of sensing film, including a first layer of Y-direction sensing elements and a second layer of X-direction sensing elements. The scanning circuity 408 (via the sensor interface circuitry 404) can continually, periodically, or aperiodically scan along the sensing elements to detect a change in capacitance caused by a user's finger and/or an electric charge carrying component such as a stylus.

At block 1604, the scanning circuitry 408 determines whether an input is detected by determining whether a touch is identified at the touch sensor 122. For example, the scanning circuitry 408 may detect an input by detecting a change in capacitance at a location of the touch sensor 122. If the scanning circuitry 408 does not detect input (block 1604: NO), control advances to block 1602 at which the scanning circuitry 408 continues to monitor the touch sensor(s) 122 to detect a touch. If the scanning circuitry 408 detects input (block 1604: YES), control advances to block 1606.

At block 1606, example location calculator circuitry (location calculator circuitry 414) determines a location(s) of the touch based on data received from the touch sensor 122. For example, the location calculator circuitry 414 can identify an element of the key matrix with the greatest change in capacitance and calculate the touch position(s) within the layers of the touch sensor 122.

At block 1608, example scan code generating circuitry (e.g., scan code generating circuitry 418) identifies a key(s) associated with the determined location(s) of the touch to identify an intended keystroke(s). For example, the scan code generating circuitry 418 may search the determined location against a character map to identify the key corresponding to that location. At block 1610, the scan code generating circuitry 418 generates a scan code corresponding to the identified keystroke(s). For example, the scan code generating circuitry 418 can convert the identified keystroke into a binary code that the electronic device 102 can understand and recognize as the respective keystroke. The scan code can be an ASCII code, a Unicode, etc.

At block 1612, the scan code generating circuitry 418 stores the scan code in a buffer. For example, the scan code generating circuitry 418 can store the scan code in a buffer and store the buffer in example memory (e.g., memory 420).

FIG. 17 is a flowchart representative of example machine readable instructions and/or example operations 1700 that may be executed and/or instantiated by processor circuitry to process an input via an example tactile capacitive keyboard (e.g., tactile capacitive keyboard 120). The machine readable instructions and/or the operations 1700 of FIG. 17 begin at block 1702, at which the example electronic device 102 detects the example tactile capacitive keyboard 120 via example input/output circuitry (e.g., input/output circuitry 112). For example, a user may connect the tactile capacitive keyboard 120 to the electronic device 102 via a wired and/or wireless connection. The input/output circuitry 112 can detect the tactile capacitive keyboard 120 when the keyboard 120 is connected to a port (e.g., a USB port, etc.) of the electronic device 102.

At block 1704, example keyboard controller circuitry (e.g., keyboard controller circuitry 126) retrieves, receives, accesses, and/or obtains data for the tactile capacitive keyboard 120. For example, the keyboard controller circuitry 126 retrieves keyboard information 424 from the database 410 of the keyboard circuitry 124. The keyboard information 424 can include, for example, a device identifier, a serial number for the tactile capacitive keyboard 120, and data regarding communication protocol(s) between the keyboard 120 and the keyboard controller circuitry 126. For example, the keyboard information 424 can include information about how the keyboard 120 is structured to report input data, such as polling rate and scan code type, so the keyboard controller circuitry 126 can properly prepare to receive this information.

At block 1706, example monitoring circuitry (monitoring circuitry 504) of the keyboard controller circuitry 126 monitors the keyboard circuitry 124 to detect a scan code corresponding to a keystroke (e.g., an input received at the tactile capacitive keyboard 120). For example, the monitoring circuitry 504 can monitor the keyboard circuitry 124 via example keyboard interface circuitry (e.g., keyboard interface circuitry 502). In some examples, the monitoring circuitry 504 monitors the keyboard circuitry 124 by periodically polling the keyboard circuitry 124 to determine whether a scan code is available for processing. For example, the monitoring circuitry 504 may send a signal such as a token to the keyboard circuitry 124 to request data corresponding to a scan code. In some examples, the monitoring circuitry 504 polls the keyboard circuitry 124 at a polling rate of 1,000 Hz.

At block 1708, the monitoring circuitry 504 determines whether a scan code is detected at the keyboard circuitry 124. For example, the monitoring circuitry 504 may receive a signal from the keyboard 120 such as a handshake, that a scan code is available for processing. If the monitoring circuitry 504 determines that a scan is not detected (block 1708: NO), control advances back to block 1706 at which the monitoring circuitry 504 continues to poll the keyboard circuitry 124. If the monitoring circuitry 504 determines that a scan is detected (block 1708: YES), control advances to block 1710.

At block 1710, the monitoring circuitry 504 receives, retrieves, accesses, and/or obtains the scan code from the keyboard circuitry 124. For example, the keyboard circuitry 124 may send (e.g., via example interface circuitry 422) the scan code to the monitoring circuitry 504 as a reply to a poll request from the monitoring circuitry 504. At block 1712, the monitoring circuitry 504 can store the scan code in a buffer of example memory (e.g., memory 512). For example, the monitoring circuitry 504 can store the scan code in a buffer of memory 512 within the keyboard controller circuitry 126 and/or other memory in communication with the electronic device 102.

At block 1714, example interrupt circuitry (e.g., interrupt circuitry 508) generates an interrupt request to a processor to notify the processor that the scan code needs to be processed. In some examples, the interrupt circuitry 508 sends the interrupt request to processing circuitry of the electronic device 102, such a processor circuitry 108 and/or other processing circuitry. In some examples, the interrupt circuitry 508 sends the interrupt request to acceleration circuitry (e.g., acceleration circuitry 130) that implements an accelerator.

At block 1716, the processor circuitry 108 and/or the acceleration circuitry 130 processes the scan code. For example, the processor circuitry 108 and/or the acceleration circuitry 130 can process the scan code to identify a corresponding keystroke and determine whether the keystroke corresponds to a system command. In response to determining that the scan code does not correspond to the system command, the processor circuitry 108 and/or the acceleration circuitry 130 can transmit the keystroke to an application that is awaiting an input received from the tactile capacitive keyboard 120.

FIG. 18 is a block diagram of an example processor platform 1800 structured to execute and/or instantiate the machine readable instructions and/or the operations of FIGS. 16-17 to implement the apparatus of FIGS. 1, 4, 5, 6, and/or 7. The processor platform 1800 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing device.

The processor platform 1800 of the illustrated example includes processor circuitry 1812. The processor circuitry 1812 of the illustrated example is hardware. For example, the processor circuitry 1812 can be implemented by one or more integrated circuits, logic circuits, FPGAs, microprocessors, CPUs, GPUs, DSPs, and/or microcontrollers from any desired family or manufacturer. The processor circuitry 1812 may be implemented by one or more semiconductor based (e.g., silicon based) devices. In this example, the processor circuitry 1812 implements example processor circuitry 108, example input/output circuitry 112, example user interface circuitry 114, example display screen interface circuitry 128, example keyboard controller circuitry 126, including example keyboard interface circuitry 502, example monitoring circuitry 504, example interrupt circuitry 508, and example acceleration interface circuitry 510, and/or example keyboard circuitry 124, including example touch circuitry 402, example sensor interface circuitry 404, example scanning circuitry 408, example location calculator circuitry 414, and example interface circuitry 422.

The processor circuitry 1812 of the illustrated example includes a local memory 1813 (e.g., a cache, registers, etc.). The processor circuitry 1812 of the illustrated example is in communication with a main memory including a volatile memory 1814 and a non-volatile memory 1816 by a bus 1818. The volatile memory 1814 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1816 may be implemented by flash memory and/or any other desired type of memory device. Access to the main memory 1814, 1816 of the illustrated example is controlled by a memory controller 1817.

The processor platform 1800 of the illustrated example also includes interface circuitry 1820. The interface circuitry 1820 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1822 are connected to the interface circuitry 1820. The input device(s) 1822 permit(s) a user to enter data and/or commands into the processor circuitry 1812. The input device(s) 1822 can be implemented by, for example, an audio sensor, a microphone, a camera (still or video), a keyboard, a button, a mouse, a touchscreen, a track-pad, a trackball, an isopoint device, and/or a voice recognition system.

One or more output devices 1824 are also connected to the interface circuitry 1820 of the illustrated example. The output device(s) 1824 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1820 of the illustrated example, thus, typically includes a graphics driver card, a graphics driver chip, and/or graphics processor circuitry such as a GPU.

The interface circuitry 1820 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1826. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 1800 of the illustrated example also includes one or more mass storage devices 1828 to store software and/or data. Examples of such mass storage devices 1828 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine executable instructions 1832, which may be implemented by the machine readable instructions of FIGS. 16-17, may be stored in the mass storage device 1828, in the volatile memory 1814, in the non-volatile memory 1816, and/or on a removable non-transitory computer readable storage medium such as a CD or DVD.

FIG. 19 is a block diagram of an example implementation of the processor circuitry 1812 of FIG. 18. In this example, the processor circuitry 1812 of FIG. 18 is implemented by a general purpose microprocessor 1900. The general purpose microprocessor circuitry 1900 executes some or all of the machine readable instructions of the flowcharts of FIGS. 16-17 to effectively instantiate the circuitry of FIGS. 1, 4, 5, 6, and/or 7 as logic circuits to perform the operations corresponding to those machine readable instructions. In some such examples, the circuitry of FIGS. 1, 4, 5, 6, and/or 7 is instantiated by the hardware circuits of the microprocessor 1900 in combination with the instructions. For example, the microprocessor 1900 may implement multi-core hardware circuitry such as a CPU, a DSP, a GPU, an XPU, etc. Although it may include any number of example cores 1902 (e.g., 1 core), the microprocessor 1900 of this example is a multi-core semiconductor device including N cores. The cores 1902 of the microprocessor 1900 may operate independently or may cooperate to execute machine readable instructions. For example, machine code corresponding to a firmware program, an embedded software program, or a software program may be executed by one of the cores 1902 or may be executed by multiple ones of the cores 1902 at the same or different times. In some examples, the machine code corresponding to the firmware program, the embedded software program, or the software program is split into threads and executed in parallel by two or more of the cores 1902. The software program may correspond to a portion or all of the machine readable instructions and/or operations represented by the flowcharts of FIGS. 16-17.

The cores 1902 may communicate by a first example bus 1904. In some examples, the first bus 1904 may implement a communication bus to effectuate communication associated with one(s) of the cores 1902. For example, the first bus 1904 may implement at least one of an Inter-Integrated Circuit (I2C) bus, a Serial Peripheral Interface (SPI) bus, a PCI bus, or a PCIe bus. Additionally or alternatively, the first bus 1904 may implement any other type of computing or electrical bus. The cores 1902 may obtain data, instructions, and/or signals from one or more external devices by example interface circuitry 1906. The cores 1902 may output data, instructions, and/or signals to the one or more external devices by the interface circuitry 1906. Although the cores 1902 of this example include example local memory 1920 (e.g., Level 1 (L1) cache that may be split into an L1 data cache and an L1 instruction cache), the microprocessor 1900 also includes example shared memory 1910 that may be shared by the cores (e.g., Level 2 (L2_ cache)) for high-speed access to data and/or instructions. Data and/or instructions may be transferred (e.g., shared) by writing to and/or reading from the shared memory 1910. The local memory 1920 of each of the cores 1902 and the shared memory 1910 may be part of a hierarchy of storage devices including multiple levels of cache memory and the main memory (e.g., the main memory 1814, 1816 of FIG. 18). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1902 may be referred to as a CPU, DSP, GPU, etc., or any other type of hardware circuitry. Each core 1902 includes control unit circuitry 1914, arithmetic and logic (AL) circuitry (sometimes referred to as an ALU) 1916, a plurality of registers 1918, the L1 cache 1920, and a second example bus 1922. Other structures may be present. For example, each core 1902 may include vector unit circuitry, single instruction multiple data (SIMD) unit circuitry, load/store unit (LSU) circuitry, branch/jump unit circuitry, floating-point unit (FPU) circuitry, etc. The control unit circuitry 1914 includes semiconductor-based circuits structured to control (e.g., coordinate) data movement within the corresponding core 1902. The AL circuitry 1916 includes semiconductor-based circuits structured to perform one or more mathematic and/or logic operations on the data within the corresponding core 1902. The AL circuitry 1916 of some examples performs integer based operations. In other examples, the AL circuitry 1916 also performs floating point operations. In yet other examples, the AL circuitry 1916 may include first AL circuitry that performs integer based operations and second AL circuitry that performs floating point operations. In some examples, the AL circuitry 1916 may be referred to as an Arithmetic Logic Unit (ALU). The registers 1918 are semiconductor-based structures to store data and/or instructions such as results of one or more of the operations performed by the AL circuitry 1916 of the corresponding core 1902. For example, the registers 1918 may include vector register(s), SIMD register(s), general purpose register(s), flag register(s), segment register(s), machine specific register(s), instruction pointer register(s), control register(s), debug register(s), memory management register(s), machine check register(s), etc. The registers 1918 may be arranged in a bank as shown in FIG. 19. Alternatively, the registers 1918 may be organized in any other arrangement, format, or structure including distributed throughout the core 1902 to shorten access time. The second bus 1922 may implement at least one of an I2C bus, a SPI bus, a PCI bus, or a PCIe bus

Each core 1902 and/or, more generally, the microprocessor 1900 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1900 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 20 is a block diagram of another example implementation of the processor circuitry 1812 of FIG. 18. In this example, the processor circuitry 1812 is implemented by FPGA circuitry 2000. The FPGA circuitry 2000 can be used, for example, to perform operations that could otherwise be performed by the example microprocessor 1900 of FIG. 19 executing corresponding machine readable instructions. However, once configured, the FPGA circuitry 2000 instantiates the machine readable instructions in hardware and, thus, can often execute the operations faster than they could be performed by a general purpose microprocessor executing the corresponding software.

More specifically, in contrast to the microprocessor 1900 of FIG. 19 described above (which is a general purpose device that may be programmed to execute some or all of the machine readable instructions represented by the flowcharts of FIGS. 16-17 but whose interconnections and logic circuitry are fixed once fabricated), the FPGA circuitry 2000 of the example of FIG. 20 includes interconnections and logic circuitry that may be configured and/or interconnected in different ways after fabrication to instantiate, for example, some or all of the machine readable instructions represented by the flowcharts of FIGS. 16-17. In particular, the FPGA 2000 may be thought of as an array of logic gates, interconnections, and switches. The switches can be programmed to change how the logic gates are interconnected by the interconnections, effectively forming one or more dedicated logic circuits (unless and until the FPGA circuitry 2000 is reprogrammed). The configured logic circuits enable the logic gates to cooperate in different ways to perform different operations on data received by input circuitry. Those operations may correspond to some or all of the software represented by the flowcharts of FIGS. 16-17. As such, the FPGA circuitry 2000 may be structured to effectively instantiate some or all of the machine readable instructions of the flowcharts of FIGS. 16-17 as dedicated logic circuits to perform the operations corresponding to those software instructions in a dedicated manner analogous to an ASIC. Therefore, the FPGA circuitry 2000 may perform the operations corresponding to the some or all of the machine readable instructions of FIG. 18 faster than the general purpose microprocessor can execute the same.

In the example of FIG. 20, the FPGA circuitry 2000 is structured to be programmed (and/or reprogrammed one or more times) by an end user by a hardware description language (HDL) such as Verilog. The FPGA circuitry 2000 of FIG. 20, includes example input/output (I/O) circuitry 2002 to obtain and/or output data to/from example configuration circuitry 2004 and/or external hardware (e.g., external hardware circuitry) 2006. For example, the configuration circuitry 2004 may implement interface circuitry that may obtain machine readable instructions to configure the FPGA circuitry 2000, or portion(s) thereof. In some such examples, the configuration circuitry 2004 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 2006 may implement the microprocessor 1900 of FIG. 19. The FPGA circuitry 2000 also includes an array of example logic gate circuitry 2008, a plurality of example configurable interconnections 2010, and example storage circuitry 2012. The logic gate circuitry 2008 and interconnections 2010 are configurable to instantiate one or more operations that may correspond to at least some of the machine readable instructions of FIG. 18 and/or other desired operations. The logic gate circuitry 2008 shown in FIG. 20 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2008 to enable configuration of the electrical structures and/or the logic gates to form circuits to perform desired operations. The logic gate circuitry 2008 may include other electrical structures such as look-up tables (LUTs), registers (e.g., flip-flops or latches), multiplexers, etc.

The interconnections 2010 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2008 to program desired logic circuits.

The storage circuitry 2012 of the illustrated example is structured to store result(s) of the one or more of the operations performed by corresponding logic gates. The storage circuitry 2012 may be implemented by registers or the like. In the illustrated example, the storage circuitry 2012 is distributed amongst the logic gate circuitry 2008 to facilitate access and increase execution speed.

The example FPGA circuitry 2000 of FIG. 20 also includes example Dedicated Operations Circuitry 2014. In this example, the Dedicated Operations Circuitry 2014 includes special purpose circuitry 2016 that may be invoked to implement commonly used functions to avoid the need to program those functions in the field. Examples of such special purpose circuitry 2016 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2000 may also include example general purpose programmable circuitry 2018 such as an example CPU 2020 and/or an example DSP 2022. Other general purpose programmable circuitry 2018 may additionally or alternatively be present such as a GPU, an XPU, etc., that can be programmed to perform other operations.

Although FIGS. 19 and 20 illustrate two example implementations of the processor circuitry 1812 of FIG. 18, many other approaches are contemplated. For example, as mentioned above, modern FPGA circuitry may include an on-board CPU, such as one or more of the example CPU 2020 of FIG. 20. Therefore, the processor circuitry 1812 of FIG. 18 may additionally be implemented by combining the example microprocessor 1900 of FIG. 19 and the example FPGA circuitry 2000 of FIG. 20. In some such hybrid examples, a first portion of the machine readable instructions represented by the flowcharts of FIGS. 16-17 may be executed by one or more of the cores 1902 of FIG. 19, a second portion of the machine readable instructions represented by the flowcharts of FIGS. 16-17 may be executed by the FPGA circuitry 2000 of FIG. 20, and/or a third portion of the machine readable instructions represented by the flowcharts of FIGS. 16-17 may be executed by an ASIC. It should be understood that some or all of the circuitry of FIG. 2 may, thus, be instantiated at the same or different times. Some or all of the circuitry may be instantiated, for example, in one or more threads executing concurrently and/or in series. Moreover, in some examples, some or all of the circuitry of FIGS. 1, 4, 5, 6, and/or 7 may be implemented within one or more virtual machines and/or containers executing on the microprocessor.

In some examples, the processor circuitry 1812 of FIG. 18 may be in one or more packages. For example, the processor circuitry 1900 of FIG. 19 and/or the FPGA circuitry 2000 of FIG. 20 may be in one or more packages. In some examples, an XPU may be implemented by the processor circuitry 1812 of FIG. 18, which may be in one or more packages. For example, the XPU may include a CPU in one package, a DSP in another package, a GPU in yet another package, and an FPGA in still yet another package.

From the foregoing, it will be appreciated that example systems, methods, apparatus, and articles of manufacture have been disclosed that provide for reduce end-to-end system latency associated with a keyboard input by enabling little to no peripheral latency and/or reporting latency. Disclosed systems, methods, apparatus, and articles of manufacture improve the efficiency of using a computing device by quickly processing an input received via an example tactile capacitive keyboard to reduce end-to-end system latency. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture for image sensor selection for electronic user devices are disclosed herein. Further examples and combinations thereof include the following:

Example 1 includes a compute system comprising a keyboard including a housing, a plurality of keys, and a touch sensor positioned between the housing and at least one of the plurality of keys; keyboard circuitry to detect a signal output by the touch sensor, the signal corresponding to a keystroke, and generate a code corresponding to the detected signal; and processor circuitry to process the code to effect the keystroke.

Example 2 includes the compute system of claim 1, wherein the touch sensor includes an adjustable sensitivity.

Example 3 includes the compute system of any of examples 1-2, wherein the keystroke includes at least one of the plurality of keys being depressed at least a distance that satisfies a threshold distance, the sensitivity of the touch sensor corresponding to the threshold distance.

Example 4 includes the compute system of any of examples 1-3, wherein the sensitivity of the touch sensor is increasable to reduce the threshold distance.

Example 5 includes the compute system of any of examples 1-4, wherein the touch sensor is a capacitive touch sensor.

Example 6 includes the compute system of any of examples 1-5, wherein the keystroke includes the touch sensor sensing a presence of a finger or object within a threshold distance above at least one of the plurality of keys.

Example 7 includes the compute system of any of examples 1-6, wherein ones of the plurality of keys include a flexible support below a keycap, the keyboard circuitry to detect the signal output by the touch sensor before the flexible support is fully compressed. In some examples, the flexible support is a dome. In some examples, the flexible support is a rubber dome.

Example 8 includes the compute system of any of examples 1-7, wherein the keyboard circuitry is to monitor the touch sensor at a scan rate of approximately 250 Hertz.

Example 9 includes the compute system of any of examples 1-8, wherein the processor circuitry is to monitor the keyboard circuitry at a polling rate between about 400 Hertz and about 1,000 Hertz.

Example 10 includes the compute system of any of examples 1-9, wherein the processor circuitry is to process the code by determining if the scan code corresponds to a system command, and in response to determining that the code does not correspond to the system command, transmitting the code to an application.

Example 11 includes the compute system of any of examples 1-10, wherein the processor circuitry includes a hardware accelerator.

Example 12 includes the compute system of any of examples 1-11, further including keyboard controller circuitry, the keyboard controller circuitry to monitor the keyboard circuitry, the keyboard controller circuitry communicatively coupled to the hardware accelerator, wherein the keyboard controller circuitry is to receive the scan code from the keyboard circuitry and transmit the code to the hardware accelerator.

Example 13 includes the compute system of any of examples 1-12, wherein the keystroke includes a gesture within a threshold distance above at least one of the plurality of keys, the gesture corresponding to a command.

Example 14 includes the compute system of example 13, wherein the gesture includes a sliding gesture across the at least one of the plurality of keys.

Example 15 includes the compute system of any of examples 13-14, wherein the command is one of display brightness adjustment, volume adjustment, or touch sensor sensitivity adjustment.

Example 16 includes the compute system of any of examples 1-15, wherein the touch sensor is a first touch sensor that is positioned below first ones of the plurality of keys, the keyboard including a second touch sensor positioned below at least one key of the plurality of keys that is different that the first ones of the plurality of keys.

Example 17 includes at least one non-transitory computer readable storage medium comprising instructions that, when executed, cause processing circuitry to at least detect a signal output by a touch sensor, the signal corresponding to a keystroke, the touch sensor positioned between a housing and at least one of a plurality of keys associated with a keyboard, generate a scan code corresponding to the detected signal, and in response to determining the scan code is ready to be processed, process the scan code to effect the keystroke.

Example 18 includes the at least one non-transitory computer readable medium of example 17, wherein the touch sensor has an adjustable sensitivity and the instructions cause the processing circuitry to adjust the sensitivity to a first sensitivity when a first application is operating on a device coupled to the keyboard and to adjust the sensitivity to a second sensitivity different than the first sensitivity when a second application is operating on the device.

Example 19 includes the at least one non-transitory computer readable medium of any of examples 17-18, wherein the touch sensor has an adjustable sensitivity and the keystroke includes at least one of the plurality of keys adjacent the touch sensor being depressed at least a distance that satisfies a threshold distance, the sensitivity of the touch sensor corresponding to the threshold distance.

Example 20 includes the at least one non-transitory computer readable medium of any of examples 17-19, wherein the instructions, when executed, cause the processing circuitry to increase the sensitivity of the touch sensor to reduce the threshold distance.

Example 21 includes the at least one non-transitory computer readable medium of any of examples 17-20, wherein the touch sensor is a capacitive touch sensor.

Example 22 includes the at least one non-transitory computer readable medium of any of examples 17-21, wherein the keystroke includes the touch sensor sensing a presence of a finger or object within a threshold distance above at least one of the plurality of keys adjacent the touch sensor.

Example 23 includes the at least one non-transitory computer readable medium of any of examples 17-22, wherein ones of the plurality of keys include a rubber dome below a keycap, and wherein the instructions, when executed, cause the processing circuitry to detect the signal output by the touch sensor before the rubber dome is fully compressed.

Example 24 includes the at least one non-transitory computer readable medium of any of examples 17-23, wherein the instructions, when executed, cause the processing circuitry to monitor the touch sensor to at a scan rate of approximately 250 Hertz to detect the signals output by the touch sensor.

Example 25 includes the at least one non-transitory computer readable medium of any of examples 17-24, wherein the instructions, when executed, cause the processing circuitry to monitor the keyboard at a polling rate between about 400 Hertz and about 1,000 Hertz to determine whether the scan code is ready to be processed.

Example 26 includes the at least one non-transitory computer readable medium of any of examples 17-25, wherein the instructions, when executed, cause the processing circuitry to process the scan code by determining if the scan code corresponds to a system command, and in response to determining that the scan code does not correspond to the system command, transmitting the scan code to an application.

Example 27 includes the at least one non-transitory computer readable medium of any of examples 17-26, wherein the processing circuitry includes a hardware accelerator, the hardware accelerator to process the scan code.

Example 28 includes the at least one non-transitory computer readable medium of any of examples 17-27, wherein the keystroke includes a gesture within a threshold distance above at least one of the plurality of keys, the gesture corresponding to a command.

Example 29 includes the at least one non-transitory computer readable medium of example 28, wherein the gesture includes a sliding gesture across the at least one of the plurality of keys.

Example 30 includes the at least one non-transitory computer readable medium of any of examples 28-29, wherein the command is one of display brightness adjustment, volume adjustment, or touch sensor sensitivity adjustment.

Example 31 includes the at least one non-transitory computer readable medium of any of examples 17-30, wherein the touch sensor is a first touch sensor that is positioned below first ones of the plurality of keys, and wherein the instructions, when executed, cause the processing circuitry to detect signals output by a second touch sensor positioned below at least one key of the plurality of keys that is different that the first ones of the plurality of keys.

Example 32 includes a method comprising detecting, by executing instructions with at least one processor, a signal output by a touch sensor, the signal corresponding to a keystroke, the touch sensor positioned between a housing and a key associated with a keyboard; generating, by executing instructions with the at least one processor, a key code corresponding to the detected signal, determining, by executing instructions with the at least one processor, whether the key code is ready to be processed; and processing, by executing instructions with the at least one processor, the key code to effect the keystroke.

Example 33 includes the method of example 32, wherein a sensitivity of the touch sensor is programmable.

Example 34 includes the method of any of examples 32-33, wherein the keystroke includes the key being depressed at least a distance that satisfies a threshold distance, the sensitivity of the touch sensor corresponding to the threshold distance.

Example 35 includes the method of any of examples 32-34, further including increasing the sensitivity of the touch sensor to reduce the threshold distance.

Example 36 includes the method of any of examples 32-35, wherein the touch sensor is a capacitive touch sensor.

Example 37 includes the method of any of examples 32-36, wherein the keystroke includes the touch sensor sensing a presence of a finger or object within a threshold distance above at least one of the plurality of keys.

Example 38 includes the method of any of examples 32-37, wherein the key includes a keycap and a rubber dome positioned under the keycap, the method including detecting the signal output by the touch sensor before the rubber dome is fully compressed.

Example 39 includes the method of any of examples 32-38, further including monitoring the touch sensor at a scan rate of approximately 250 Hertz to detect the signals output by the touch sensor.

Example 40 includes the method of any of examples 32-39, further including monitoring the keyboard at a polling rate between about 400 Hertz and about 1,000 Hertz to determine if the key code is ready to be processed.

Example 41 includes the method of any of examples 32-40, wherein the processing includes determining if the key code corresponds to a system command, and in response to determining that the key code does not correspond to the system command, transmitting the key code to an application.

Example 42 includes the method of any of examples 32-41, wherein the at least one processor includes a hardware accelerator, and wherein the hardware accelerator processes the key code.

Example 43 includes the method of any of examples 32-42, further including receiving the scan code at a keyboard controller when the key code is ready for processing, the keyboard controller to transmit the key code to the hardware accelerator for processing.

Example 44 includes the method of any of examples 32-43, wherein the keystroke includes a gesture within a threshold distance above at least one of the plurality of keys, the gesture corresponding to a command.

Example 45 includes the method of example 44, wherein the gesture includes a sliding gesture across the at least one of the plurality of keys.

Example 46 includes the method of any of examples 44-45, wherein the command is one of display brightness adjustment, volume adjustment, or touch sensor sensitivity adjustment.

Example 47 includes the method of any of examples 32-46, wherein the touch sensor is a first touch sensor that is positioned below first ones of the plurality of keys, the keyboard including a second touch sensor positioned below at least one key of the plurality of keys that is different that the first ones of the plurality of keys.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. A compute system comprising:
a keyboard including:
a housing;
a plurality of keys; and
a touch sensor positioned between the housing and at least one of the plurality of keys;
keyboard circuitry to:
detect a signal output by the touch sensor, the signal corresponding to a keystroke; and
generate a code corresponding to the detected signal; and
processor circuitry to process the code to effect the keystroke.

2. The compute system of claim 1, wherein the touch sensor includes an adjustable sensitivity.

3. The compute system of claim 2, wherein the keystroke includes at least one of the plurality of keys being depressed at least a distance that satisfies a threshold distance, the sensitivity of the touch sensor corresponding to the threshold distance.

4. The compute system of claim 3, wherein the sensitivity of the touch sensor is increasable to reduce the threshold distance.

5. The compute system of claim 1, wherein the touch sensor is a capacitive touch sensor.

6. The compute system of claim 5, wherein the keystroke includes the touch sensor sensing a presence of a finger or object within a threshold distance above at least one of the plurality of keys.

7. The compute system of claim 1, wherein ones of the plurality of keys include a flexible support below a keycap, the keyboard circuitry to detect the signal output by the touch sensor before the flexible support is fully compressed.

8. The compute system of claim 1, wherein the keyboard circuitry is to monitor the touch sensor at a scan rate of approximately 250 Hertz.

9. The compute system of claim 1, wherein the processor circuitry is to monitor the keyboard circuitry at a polling rate between about 400 Hertz and about 1,000 Hertz.

10. The compute system of claim 1, wherein the processor circuitry is to process the code by:
determining if the code corresponds to a system command; and
in response to determining that the code does not correspond to the system command, transmitting the code to an application.

11. The compute system of claim 10, wherein the processor circuitry includes a hardware accelerator.

12. The compute system of claim 11, further including keyboard controller circuitry, the keyboard controller circuitry to monitor the keyboard circuitry, the keyboard controller circuitry communicatively coupled to the hardware accelerator, wherein the keyboard controller circuitry is to receive the scan code from the keyboard circuitry and transmit the code to the hardware accelerator.

13. The compute system of claim 1, wherein the keystroke includes a gesture within a threshold distance above at least one of the plurality of keys, the gesture corresponding to a command.

14. The compute system of claim 13, wherein the gesture includes a sliding gesture across the at least one of the plurality of keys.

15. The compute system of claim 14, the command is one of display brightness adjustment, volume adjustment, or touch sensor sensitivity adjustment.

16. The compute system of claim 1, wherein the touch sensor is a first touch sensor that is positioned below first ones of the plurality of keys, the keyboard including a second touch sensor positioned below at least one key of the plurality of keys that is different that the first ones of the plurality of keys.

17. At least one non-transitory computer readable storage medium comprising instructions that, when executed, cause processing circuitry to at least:
detect a signal output by a touch sensor, the signal corresponding to a keystroke, the touch sensor positioned between a housing and at least one of a plurality of keys associated with a keyboard;
generate a scan code corresponding to the detected signal; and
in response to determining the scan code is ready to be processed, process the scan code to effect the keystroke.

18. The at least one non-transitory computer readable storage medium of claim 17, wherein the touch sensor has an adjustable sensitivity and the instructions cause the processing circuitry to adjust the sensitivity to a first sensitivity when a first application is operating on a device coupled to the keyboard and to adjust the sensitivity to a second sensitivity different than the first sensitivity when a second application is operating on the device.

19. The at least one non-transitory computer readable storage medium of claim 17, wherein the touch sensor has an adjustable sensitivity and the keystroke includes at least one of the plurality of keys adjacent the touch sensor being depressed at least a distance that satisfies a threshold distance, the sensitivity of the touch sensor corresponding to the threshold distance.

20. The at least one non-transitory computer readable storage medium of claim 19, wherein the instructions, when executed, cause the processing circuitry to increase the sensitivity of the touch sensor to reduce the threshold distance.

21.-31. (canceled)

32. A method comprising:
detecting, by executing instructions with at least one processor, a signal output by a touch sensor, the signal corresponding to a keystroke, the touch sensor positioned between a housing and a key associated with a keyboard;
generating, by executing instructions with the at least one processor, a key code corresponding to the detected signal;
determining, by executing instructions with the at least one processor, whether the key code is ready to be processed; and
processing, by executing instructions with the at least one processor, the key code to effect the keystroke.

33. The method of claim 32, wherein a sensitivity of the touch sensor is programmable.

34. The method of claim 33, wherein the keystroke includes the key being depressed at least a distance that satisfies a threshold distance, the sensitivity of the touch sensor corresponding to the threshold distance.

35. The method of claim 34, further including increasing the sensitivity of the touch sensor to reduce the threshold distance.

36.-43. (canceled)

44. The method of claim 32, wherein the keystroke includes a gesture within a threshold distance above at least one of the plurality of keys, the gesture corresponding to a command.

45.-47. (canceled)
